(19) United States
(12) Patent Application Publication
(10) Pub. No.: US 2026/0123270 A1
(43) Pub. Date: Apr. 30, 2026

(54) COMPOSITIONS AND METHODS FOR MODIFYING PEROVSKITE SURFACES

(71) Applicant: Alliance for Sustainable Energy, LLC, Golden, CO (US)

(72) Inventors: Kai ZHU, Littleton, CO (US); Fei ZHANG, Tianjin (CN)

(21) Appl. No.: 18/567,145

(22) PCT Filed: Jun. 6, 2022
(86) PCT No.: PCT/US2022/072777

§ 371 Date: Dec. 5, 2023

Related U.S. Application Data
(60) Provisional application No. 63/197,652, filed on Jun. 7, 2021.

(51) Int. Cl. H10K 85/50; H10K 30/10; H10K 30/50

(52) U.S. Cl. CPC H10K 85/50; H10K 30/10; H10K 30/50

(57) ABSTRACT

The present disclosure relates to a composition that includes a first layer having a first perovskite having a 3-dimensional (3D) crystalline structure and a second layer having a second perovskite having a 2-dimensional (2D) crystalline structure, where the 3D crystalline structure includes ABX₃, the 2D crystalline structure includes A′BX₄, A includes a first cation, B includes a second cation, X includes an anion, and A′ includes a third cation having a 2+ charge.

### CROSS-REFERENCE TO RELATED APPLICATIONS

This application claims priority from U.S. Provisional Patent Application No. 63/197,652 filed on Jun. 6, 2021, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

Organic metal halide perovskite solar cells (PSCs) have attracted significant attention due to their rapidly enhanced power conversion efficiency (PCE) from 3.8% to above 25%. However, stability of devices using such perovskites remains problematic. The use of two-dimensional (2D) perovskites based on bulky organic cations may improve both the performance and stability of three-dimensional (3D)-perovskite-based solar cells. However, the use of such 2D structures can inhibit charge transport and can result in charge extraction barrier formation, thereby inhibiting device performance. Thus, there remains a need for improved methods and compositions that can overcome these problems, while simultaneously solving the stability issues facing current 2D perovskite-containing compositions.

### SUMMARY

An aspect of the present disclosure is a composition that includes a first layer having a first perovskite having a 3-dimensional (3D) crystalline structure and a second layer having a second perovskite having a 2-dimensional (2D) crystalline structure, where the 3D crystalline structure includes ABX₃, the 2D crystalline structure includes A′BX₄, A includes a first cation, B includes a second cation, X includes an anion, and A′ includes a third cation having a 2+ charge. In some embodiments of the present disclosure, A′ may have a characteristic length between 2.60 Å and 10.10 Å. In some embodiments of the present disclosure, the 2D crystalline structure may have a monoclinic P21/c space group.

In some embodiments of the present disclosure, A′ may include at least one of N,N-dimethyl-1,3-propane diammonium (DMePDA²⁺) and/or 3-(aminomethyl)pyridinium (3-AMPY²⁺). In some embodiments of the present disclosure, the 2D crystalline structure may include DMePDAPbI₄. In some embodiments of the present disclosure, the first perovskite may include FA_{1-x-y}MAₓCs_{y}Pb(I_{1-z}Br_{z})₃, 0≤x≤1, 0≤y≤1, and 0≤z≤1. In some embodiments of the present disclosure, the composition may have a yield mobility product (φΣμ) that is between 35 cm2/Vs and 100 cm2/Vs cm²/Vs. In some embodiments of the present disclosure, the composition may have a charge-carrier lifetime that is between 1.3 microseconds and 6.0 microseconds.

In some embodiments of the present disclosure, the composition may have an out-of-plane charge transport that is between (3-8)×10⁻³ cm²V⁻¹s⁻¹ and (7-21)×10⁻² cm²V⁻¹s⁻¹. In some embodiments of the present disclosure, the second layer may uniformly cover the first layer. In some embodiments of the present disclosure, the composition may be characterized by a peak between 8.5° and 8.7°, as measured by XRD. In some embodiments of the present disclosure, the composition may be characterized by a free-carrier lifetime have a fast component value equal to at least 75 ns, as measured by photoluminescence (PL) decay. In some embodiments of the present disclosure, the composition may be characterized by a free-carrier lifetime have a slow component value equal to at least 140 ns, as measured by photoluminescence (PL) decay.

An aspect of the present disclosure is a device that includes a first layer having a first perovskite having a 3-dimensional (3D) crystalline structure and a second layer having a second perovskite having a 2-dimensional (2D) crystalline structure, where the 3D crystalline structure includes ABX₃, the 2D crystalline structure includes A′BX₄, A includes a first cation, B includes a second cation, X includes an anion, and A′ includes a third cation having a 2+ charge.

An aspect of the present disclosure is a device that includes, in order, a glass substrate, a layer that includes fluorine-doped tin oxide, a layer that includes at least one of SnO₂ and/or TiO₂, a layer that includes a 3-dimensional (3D) perovskite, a layer that includes a 2-dimensional (2D) perovskite, a layer that includes a hole-transport material (HTL), and a metal layer.

### BRIEF DESCRIPTION OF THE DRAWINGS

Some embodiments are illustrated in referenced figures of the drawings. It is intended that the embodiments and figures disclosed herein are to be considered illustrative rather than limiting.

FIGS. 1A, 1B, and 1C illustrate a perovskite, according to some embodiments of the present disclosure.

FIG. 2 illustrates 2D, 1D, and 0D perovskite structures, in Panels A, B, and C, respectively, according to some embodiments of the present disclosure.

FIG. 3A illustrates side views of the crystal structures of (Panel A) BDAPbI₄, (Panel B) DMePDAPbI₄-1, and (Panel C) DMePDAPbI₄-2 single crystals, according to some embodiments of the present disclosure. The average interlayer distances are indicated. (BDA=1,4-butane diamine and DMePDA=N,N-dimethyl-1,3-propane diammonium, both having a 2+ charge.)

FIG. 3B illustrates a side view of the crystal structure of DMePDAPbI₄-1 and the corresponding hydrogen-bonding configuration, according to some embodiments of the present disclosure.

FIG. 3C illustrates a side view of the crystal structure of DMePDAPbI₄-2 and the corresponding hydrogen-bonding configuration, according to some embodiments of the present disclosure.

FIG. 4 illustrates a composition, according to some embodiments of the present disclosure.

FIG. 5A illustrates X-ray diffraction (XRD) patterns of solution deposited DMePDAPbI₄ layers and calculated powder XRD patterns from DMePDAPbI₄-1 and DMePDAPbI₄-2 single-crystal structures, according to some embodiments of the present disclosure. X-ray source: Cu Kα radiation. Peaks labeled with “*” are from the FTO substrates.

FIG. 5B illustrates an energy profile along the transition path between DMePDAPbI₄-1 and DMePDAPbI₄-2, according to some embodiments of the present disclosure.

FIG. 5C illustrates a TRMC comparison of out-of-plane charge transport across the layers of n=1 2D perovskites, according to some embodiments of the present disclosure.

FIG. 5D illustrates J-V characteristics of PSCs based on n=1 2D perovskite layers using a device stack of FTO/compact-TiO₂/2D-perovskite/spiro-OMeTAD/Au, according to some embodiments of the present disclosure.

FIG. 6A illustrates band offsets between [PbI₆] planes and bulky organic cations with a weaker and stronger degree of H-bonding, according to some embodiments of the present disclosure. The orbitals of [PbI₆] inorganic frame is not shown in the middle of the panel for clarity.

FIG. 6B illustrates two possible arrangements of asymmetric DMePDA²⁺ cations and the sole arrangement of symmetric BDA²⁺ cations, according to some embodiments of the present disclosure.

FIG. 6C illustrates HSE+vdW calculated total DOSs of the organic cations in BDAPbI₄, DMePDAPbI₄-1 (with orientation-1 in (see FIG. 6B)), and DMePDAPbI₄-2 (with orientation-2 in (see FIG. 6B)), according to some embodiments of the present disclosure. The VBMs were set to 0.0 eV, according to some embodiments of the present disclosure.

FIG. 7 illustrates (Panel A) the chemical structure of 1,3-propane diammonium diiodine (PDAI₂) and the photo of single crystals of [PDAPbI₄]₁₅·[PDAI₂] and (Panel B) the single-crystal structure of [PDAPbI₄]₁₅·[PDAI₂], according to some embodiments of the present disclosure. Note that when the halide is Br⁻, the PDA²⁺ cannot form the typical 2D DJ phase perovskite; however, when the halide is Cl⁻, the 2D PDAPbCl₄ can form, likely since Cl⁻ ions are much smaller and not as electrostatically repulsive at this distance as iodide or bromide.

FIG. 8 illustrates a side view of the crystal structure of BDAPbI₄ and the corresponding hydrogen-bonding configuration, according to some embodiments of the present disclosure.

FIG. 9 illustrates (Panel A) the photoluminescence (PL) spectra and (Panel B) absorption spectra of DMePDAPbI₄-1 and DMePDAPbI₄-2 single crystal samples, according to some embodiments of the present disclosure. The inset shows the photographs of DMePDAPbI₄-1 and DMePDAPbI₄-2 single crystal samples.

FIG. 10A illustrates XRD data of DMePDAPbI₄ layers grown in varying DMF: DMSO solvent ratios, according to some embodiments of the present disclosure.

FIG. 10B illustrates XRD data of DMePDAPbI₄ layers grown in different combinations of solvents including DMF: GBL, DMF: NMP, DMF: CHP (1-Cyclohexyl-2-pyrrolidone), and DMF: DMSO, all at a 1:1 ratio, according to some embodiments of the present disclosure.

FIG. 10C illustrates XRD data of DMePDAPbI₄ layers after post-growth annealing temperature at varying temperatures from 60° C. to 120° C., according to some embodiments of the present disclosure. These results indicate that only the metastable DMePDAPbI₄-2 layer can be formed with the solution growth method.

FIG. 11 illustrates a comparison of out-of-plane hole transport by SCLC, according to some embodiments of the present disclosure. (Panel A) illustrates dark I-V characteristics of vertical hole-only devices based on 2D perovskite single crystals. (Panel B) illustrates statistical comparison of normalized out-of-plane hole mobilities.

FIGS. 12A, 12B, and 12C illustrate results obtained from surface layer treatment, according to some embodiments of the present disclosure. FIG. 12A illustrates a comparison of XRD patterns of layers of DMePDAPbI₄ and perovskites without (control PVK) and with DMePDAI₂ surface treatment (PVK/DMePDAI₂). X-ray source: Cu Kα radiation. FIGS. 12B and 12C illustrate a comparison of the XPS spectra of N1s and C1s for the control (FIG. 12A) and the DMePDAI₂-treated (FIG. 12C) perovskite layer.

FIG. 13A illustrates GIWAXS of (Panel A) DMePDAI₄, (Panel B) control perovskite (Control PVK), and (Panel C) DMePDAI₂-treated perovskite (PVK/DMePDAI₂) layers, according to some embodiments of the present disclosure. The incidence angle was 0.12°.

FIG. 13B illustrates radially integrated GIWAXS data from FIG. 13A, according to some embodiments of the present disclosure. The low-angle diffraction peak at about q=0.61 Å⁻¹ corresponds to about 8.57° for the layer XRD measurement using Cu Kα radiation.

FIG. 14 illustrates a top view of SEM images of (Panel A) the control and (Panel C) DMePDAI₂-treated perovskite layers (scale bar: 2 μm), according to some embodiments of the present disclosure. Cross-sectional view SEM images are illustrated in (Panel B) the control and (Panel D) DMePDAI₂-treated perovskite layers on FTO glass.

FIG. 15A illustrates AFM topography of (Panel A) the control and (Panel D) DMePDAI₂-treated perovskite layers (scale bar: 1 μm). C-AFM images of (Panel B) the control and (Panel E) DMePDAI₂-treated perovskite layers on TiO₂/FTO glass (scale bar: 1 μm).

FIG. 15B illustrates the corresponding line profiles of C-AFM obtained from the data shown in FIG. 15A based on (Panel A) the control and (Panel B) DMePDAI₂-treated perovskite layers.

FIG. 16A illustrates GIXRD patterns of perovskites without (3D PVK) and with DMePDAI₂ surface treatment (3D PVK/DMePDAI₂) where the perovskite layer treated was Cs_{0.05}FA_{0.95}PbI₃, according to some embodiments of the present disclosure. The peaks labeled with “*” are from the FTO substrate.

FIG. 16B illustrates GIXRD patterns of perovskites without (3D PVK) and with DMePDAI₂ surface treatment (3D PVK/DMePDAI₂) where the perovskite layer treated was (FAPbI₃)_{0.95}(MAPbBr₃)_{0.05}, according to some embodiments of the present disclosure. The peaks labeled with “*” are from the FTO substrate.

FIG. 16C illustrates GIXRD patterns of perovskites without (3D PVK) and with DMePDAI₂ surface treatment (3D PVK/DMePDAI₂) where the perovskite layer treated was FAPbI₃, according to some embodiments of the present disclosure. The peaks labeled with “*” are from the FTO substrate.

FIG. 17 illustrates top-view SEM images of perovskite layers without (control; Panel A) and with DMePDAI₂ surface treatment Panels (B-D), according to some embodiments of the present disclosure. The concentration of DMePDAI₂/IPA solution is varied from 0.25 mg/mL to 0.75 mg/mL as indicated. It shows that with increasing DMePDAI₂ solution concentration, the perovskite layer surface smoothness is enhanced, and the perovskite grain boundaries gradually disappear.

FIG. 18 illustrates a comparison of PL measurements of a control (untreated) and DMePDAI₂-treated perovskite layers, according to some embodiments of the present disclosure.

FIG. 19 illustrates a comparison of the TRPL measurements of the control and DMePDAI₂-treated perovskite layers, according to some embodiments of the present disclosure.

FIG. 20 illustrates a comparison of time-resolved microwave conductivity (TRMC) measurement of the control and DMePDAI₂-treated perovskite layers, according to some embodiments of the present disclosure. The control perovskite has a biexponential fitted average lifetime of 0.91 microseconds, while the DMePDAI₂-treated layers lifetime had improved lifetimes of 1.32 microseconds, respectively. The fit-extracted t=0 yield-mobility product ((Eu) value was found to be 36.9 cm²/Vs, and 39.7 cm²/Vs for the control, and DMePDAI₂ treated layers, respectively. Since the yield is normally close to unity in high-performance PSCs, the yield-mobility product can be viewed as a measurement of the charge mobility.

FIG. 21 illustrates (Panel A) ultraviolet photoelectron spectra (UPS) of a 3D perovskite layer (3D PVK) and a 2D perovskite (2D PVK) coated on top of a 3D perovskite layer, according to some embodiments of the present disclosure. The baseline 3D perovskite composition was FA_{0.85}MA_{0.1}Cs_{0.05}PbI_{2.9}Br_{0.1}. (Panel B) illustrates a schematic of energy levels of the 3D and 2D perovskites described herein.

FIG. 22 illustrates XPS spectra taken on two different spots based on a untreated perovskite layer, according to some embodiments of the present disclosure.

FIG. 23 illustrates XPS spectra taken on two different spots on the DMePDAI₂-treated perovskite layer, according to some embodiments of the present disclosure.

FIG. 24 illustrates a cross-sectional view SEM image of a DMePDAI₂-treated perovskite-based device stack, according to some embodiments of the present disclosure. (Panel A) illustrates the cell architecture (from top to bottom) Au/spiro-OMeTAD/FA_{0.85}MA_{0.1}Cs_{0.05}PbI_{2.9}Br_{0.1}/mesoporous-TiO₂/compact-TiO₂/FTO/glass. (Panel B) illustrates the cell architecture Au/spiro-OMeTAD/FA_{0.97}MA_{0.03}PbI_{2.91}Br_{0.09}/SnO₂/FTO/glass.

FIGS. 25A-C illustrate J-V characteristics of PSCs based on different perovskite compositions, according to some embodiments of the present disclosure: FIG. 25A—FA_{0.85}MA_{0.1}Cs_{0.05}PbI_{2.9}Br_{0.1}; FIG. 25B—FA_{0.97}MA_{0.03}PbI_{2.91}Br_{0.09}; and FIG. 25C—MAPbI₃. The insets are stabilized power outputs (SPOs) of the corresponding devices.

FIG. 25D illustrates the operation ISOS-L-1 stability (maximum power point tracking, in N₂, continuous one-sun illumination at ˜40° C.) of unencapsulated PSC based on FA_{0.85}MA_{0.1}Cs_{0.05}PbI_{2.9}Br_{0.1}, according to some embodiments of the present disclosure.

FIGS. 26A and 26B illustrate KPFM electrical potential and field profiling on the cross-sectional surface for devices based on (FIG. 26A) the control and (FIG. 26B) DMePDAI₂-treated perovskite layers, according to some embodiments of the present disclosure. Top: potential profile under 0 V, −1 V, and −1.5 V bias voltages. Middle: potential difference between the various applied bias voltages and 0 V. Bottom: change in electric field calculated by taking the first derivatives of the potential difference. The HTL is spiro-OMeTAD. The local voltage drop across the device is determined by the competition of equivalent resistance of different layers and interfaces, which can be related to the interface quality. Because the electron transport layer (ETL)/perovskite interface should be identical for these devices, we normalized the ETL/perovskite peak to compare the “back-contact” quality at the perovskite/HTL interfaces between the surface-treated devices. It is evident that the DMePDAI₂-treated device showed a significantly smaller perovskite/HTL electric field difference peak than that of the control perovskite devices. If consider the main junction at ETL/perovskite interface, the smaller perovskite/HTL peak indicates that the DMePDAI₂-treated device has a less leaky interface, suggesting that a better back contact quality can decrease the energy loss associated with carrier transport over the interface, enabling higher FF and Voe in devices.

FIG. 27 illustrates a statistical distribution of PCE of perovskite solar cells based on DMePDAI₂-treated perovskite layers with different concentrations, according to some embodiments of the present disclosure. The control devices are those noted with zero concentration of surface treatment.

FIG. 28 illustrates EQE spectra with integrated current densities for the corresponding devices based on FA_{0.97}MA_{0.03}PbI_{2.91}Br_{0.09}-based devices without (Control) and with DMePDAI₂ surface modification (DMePDAI₂), according to some embodiments of the present disclosure.

FIG. 29 illustrates a statistical comparison of PCEs for solar cells without (Control) and with DMePDAI₂ surface modification (DMePDAI₂) using three perovskite compositions: (Panel A) FA_{0.85}MA_{0.1}Cs_{0.05}PbI_{2.9}Br_{0.1}, (Panel B) FA_{0.97}MA_{0.03}PbI_{2.91}Br_{0.09}, and (Panel C) MAPbI₃, according to some embodiments of the present disclosure.

FIG. 30 illustrates a comparison of the moisture and thermal stability of PSCs without and with surface treatments, according to some embodiments of the present disclosure. The baseline perovskite composition is FA_{0.85}MA_{0.1}Cs_{0.05}PbI_{2.9}Br_{0.1}. The PSC without surface treatment is the control. The PSC with DMePDAI₂ treatment is denoted by DMePDAPbI₄, and the PSC with BDAI₂ surface treatment is denoted by BDAPbI₄. Here, PTAA with 5 wt % TPFB was used to avoid the effect of hygroscopic additives and thermal degradation in spiro-OMeTAD. (Panel A) illustrates a comparison of the moisture stability test of unencapsulated PSCs without and with surface treatment (as indicated) in 85% RH at room temperature for 740 h. The average PCE of unencapsulated control, BDAI₂-treated, and DMePDAI₂-treated PSCs maintained about 27%, 35%, 73% of their respective initial PCEs after 740 h ageing under >85% RH. The increased stability of DMePDAI₂-treated PSCs relative to BDAI₂-treated ones is consistent with the increased hydrophobicity. (Panel B) illustrates a comparison of the thermal stability test of unencapsulated PSCs without and with surface treatment (as indicated) heated at 85° C. for 1008 h, in dark, 5% RH. The average PCE of unencapsulated control, BDAI₂-treated, and DMePDAI₂-treated PSCs maintained about 29%, 53% and 81% of their respective initial PCEs after 1008-h ageing at 85° C.

FIG. 31 illustrates a comparison of contact angle measurement of (Panel A) BDAPbI₄ and (Panel B) DMePDAPbI₄ perovskite layers, according to some embodiments of the present disclosure.

### REFERENCE NUMBERS

| | |
|---|---|
| 100 | perovskite |
| 110 | A-cation |
| 120 | B-cation |
| 130 | X-anion |
| 400 | composition |
| 410 | first layer |
| 420 | second layer |

### DETAILED DESCRIPTION

The present disclosure may address one or more of the problems and deficiencies of the prior art discussed above. However, it is contemplated that some embodiments as disclosed herein may prove useful in addressing other problems and deficiencies in a number of technical areas. Therefore, the embodiments described herein should not necessarily be construed as limited to addressing any of the particular problems or deficiencies discussed herein.

References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

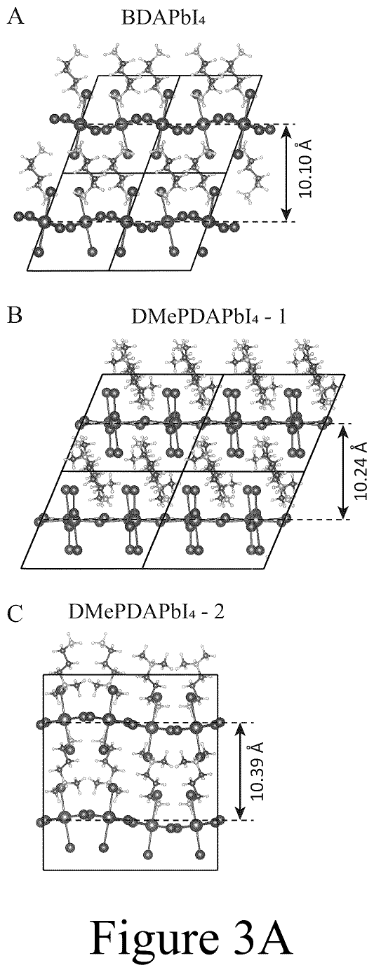

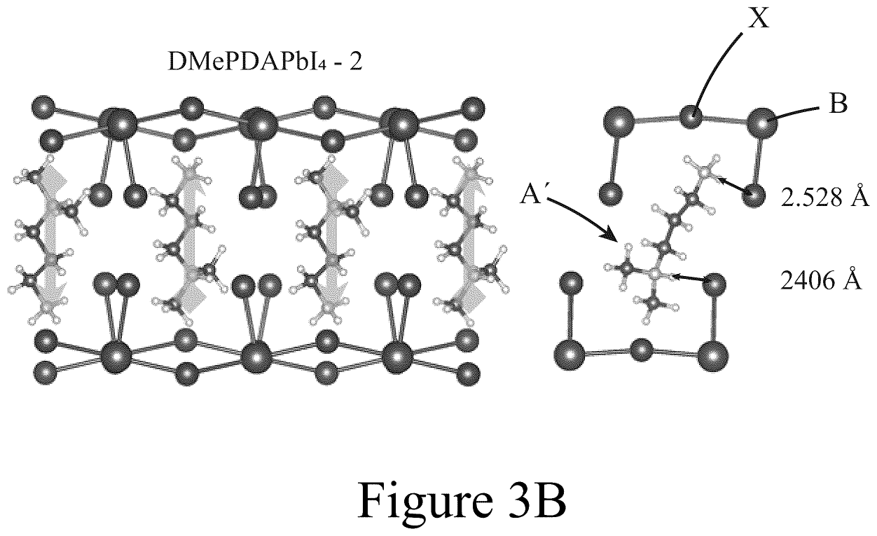

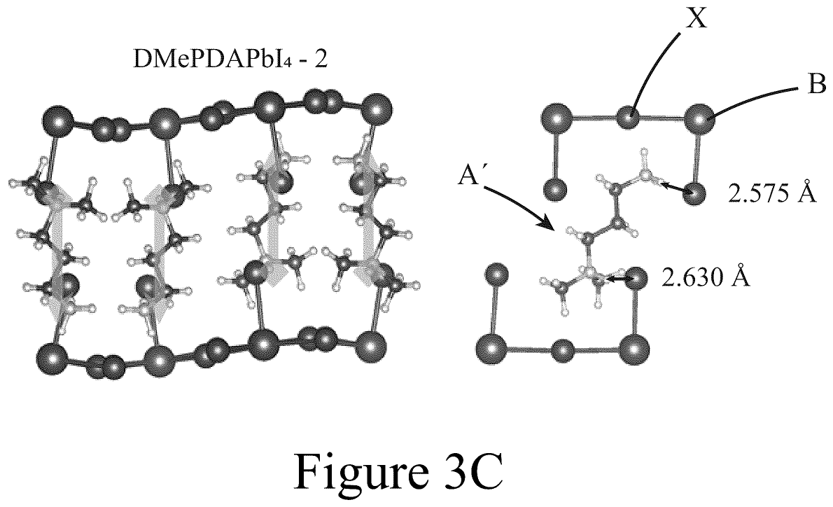

The present disclosure relates to compositions and method for modifying the surfaces of organic-inorganic halide perovskite layers (i.e., thin films) resulting in the enhanced performance and stability of PSCs utilizing the perovskite layers as active layers. For example, as shown herein, a bulky cation, e.g., N, N-dimethyl-1,3-propane diammonium (DMePDA²⁺), may be used to treat the surface of a variety of 3D perovskite layers, resulting in the formation of an additional thin solid 2D layer of a perovskite incorporating the bulky cation positioned on the surface of the underlying 3D perovskite layer. For the example of DMePDA²⁺ as the bulky cation used in the surface treatment, the resultant 2D perovskite layer formed has the composition of DMePDAPbI₄ (see FIGS. 3A, 3B, and 3C), which is discussed in more detail below. Among other things, such surface treating with a bulky cation can result in a final perovskite structure having a range of improved performance metrics and physical properties; smoother surface texture, longer charge-carrier lifetime, higher charge-carrier mobility, and a reduced surface-defect density. As shown herein, these improvements to physical properties and performance metrics can increase the efficiency of a PSC utilizing a 3D perovskite active layer that includes a 2D perovskite layer by as much as 12% to 16%, relative to devices using the identical 3D perovskite active layer, but without a 2D layer.

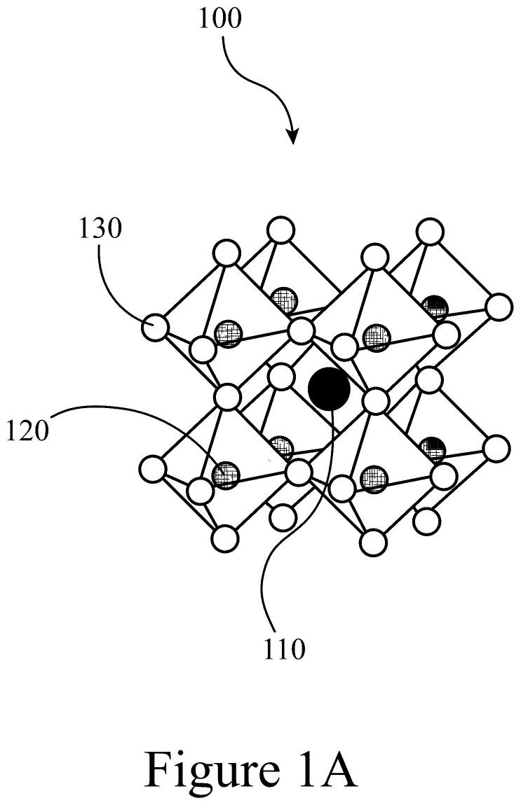

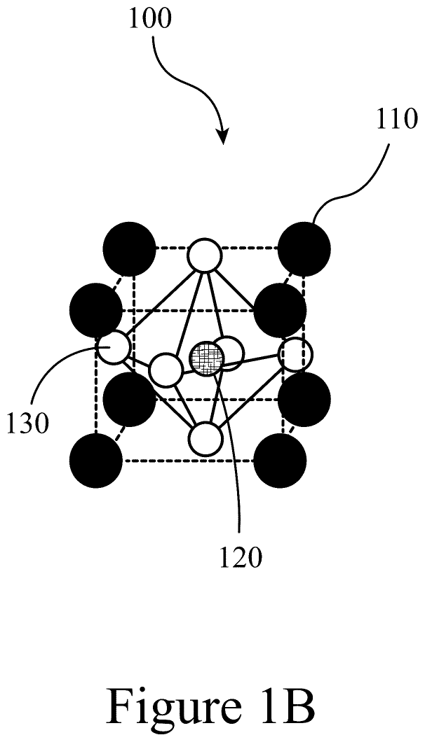

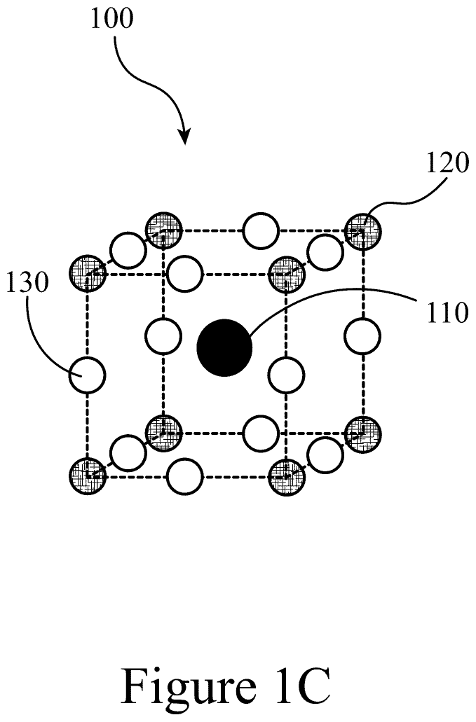

FIGS. 1A, 1B, and 1C illustrate that perovskites 100, for example halide perovskites, may organize into cubic crystalline structures with corner-sharing octahedra, as well as other crystalline structures such as tetragonal, hexagonal, and orthorhombic with either edge-or face-sharing octahedra, and may be described by the general formula ABX₃, where X (130) is an anion and A (110) and B (120) are cations, typically of different sizes. In some embodiments of the present disclosure, a perovskite may have a layered structure that includes 3D structures described above positioned between sheets of organic cations; these are often termed 2D perovskites. Mixture of the 2D and 3D phases are also possible. FIG. 1A illustrates that a perovskite 100 may be organized into eight octahedra surrounding a central A-cation 110, where each octahedra is formed by six X-anions 130 surrounding a central B-cation 120. FIG. 1B illustrates that a perovskite 100 may be visualized as a cubic unit cell, where the B-cation 120 is positioned at the center of the cube, an A-cation 110 is positioned at each corner of the cube, and an X-anion 130 is face-centered on each face of the cube. FIG. 1C illustrates that a perovskite 100 may also be visualized as a cubic unit cell, where the B-cation 120 resides at the eight corners of a cube, while the A-cation 110 is located at the center of the cube and with 12 X-anions 130 centrally located between B-cations 120 along each edge of the unit cell. For both unit cells illustrated in FIGS. 1B and 1C, the A-cations 110, the B-cations 120, and the X-anions 130 balance to the general formula ABX₃, after accounting for the fractions of each atom shared with neighboring unit cells. For example, referring to FIG. 1B, the single B-cation 120 atom is not shared with any of the neighboring unit cells. However, each of the six X-anions 130 is shared between two unit cells, and each of the eight A-cations 110 is shared between eight unit cells. So, for the unit cell shown in FIG. 1B, the stoichiometry simplifies to B=1, A=8*0.125=1, and X=6*0.5=3, or ABX₃. Similarly, referring again to FIG. 1C, since the A-cation is centrally positioned, it is not shared with any of the unit cells neighbors. However, each of the 12 X-anions 130 is shared between four neighboring unit cells, and each of the eight B-cations 120 is shared between eight neighboring unit cells, resulting in A=1, B=8*0.125=1, and X=12*0.25=3, or ABX₃. Referring again to FIG. 1C, the X-anions 130 and the B-cations 120 are shown as aligned along an axis; e.g. where the angle at the X-anion 130 between two neighboring B-cations 120 is exactly 180 degrees, referred to herein as the tilt angle. However, a perovskite 100 may have a tilt angle not equal to 180 degrees. For example, some embodiments of the present disclosure may have a tilt angle between 153 and 180 degrees.

Typical inorganic perovskites include calcium titanium oxide (calcium titanate) minerals such as, for example, CaTiO₃ and SrTiO₃. In some embodiments of the present invention, the A-cation 110 may include a nitrogen-containing organic compound such as an alkyl ammonium compound. The B-cation 120 may include a metal and the X-anion 130 may include a halogen. Additional examples for the A-cation 110 include organic cations and/or inorganic cations, for example Cs, Rb, K, Na, Li, and/or Fr. Organic A-cations 110 may be an alkyl ammonium cation, for example a C₁₋₂₀ alkyl ammonium cation, a C₁₋₆ alkyl ammonium cation, a C₂₋₆ alkyl ammonium cation, a C₁₋₅ alkyl ammonium cation, a C₁₋₄ alkyl ammonium cation, a C₁₋₃ alkyl ammonium cation, a C₁₋₂ alkyl ammonium cation, and/or a C₁ alkyl ammonium cation. Further examples of organic A-cations 110 include methylammonium (CH₃NH₃⁺), ethylammonium (CH₃CH₂NH₃⁺), propylammonium (CH₃CH₂ CH₂NH₃⁺), butylammonium (CH₃CH₂ CH₂ CH₂NH₃⁺), formamidinium (NH₂CH═NH₂⁺), hydrazinium, acetylammonium, dimethylammonium, imidazolium, guanidinium, benzylammonium, phenethylammonium, butylammonium and/or any other suitable nitrogen-containing or organic compound. In other examples, an A-cation 110 may include an alkylamine. Thus, an A-cation 110 may include an organic component with one or more amine groups. For example, an A-cation 110 may be an alkyl diamine halide such as formamidinium (CH(NH₂)₂). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. In some embodiments, an alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C₅), amyl (C₅), neopentyl (C₅), 3-methyl-2-butanyl (C₅), tertiary amyl (C₅), and n-hexyl (C₆). Additional examples of alkyl groups include n-heptyl (C₇), n-octyl (C₈) and the like.

Examples of metal B-cations 120 include, for example, lead, tin, germanium, and or any other 2+ valence state metal that can charge-balance the perovskite 100. Further examples include transition metals in the 2+ state such as Mn, Mg, Zn, Cd, and/or lanthanides such as Eu. B-cations may also include elements in the 3+ valence state, as described below, including for example, Bi, La, and/or Y. Examples for X-anions 130 include halogens: e.g. fluorine, chlorine, bromine, iodine and/or astatine. In some cases, the perovskite halide may include more than one X-anion 130, for example pairs of halogens; chlorine and iodine, bromine and iodine, and/or any other suitable pairing of halogens. In other cases, the perovskite 100 may include two or more halogens of fluorine, chlorine, bromine, iodine, and/or astatine.

Thus, the A-cation 110, the B-cation 120, and X-anion 130 may be selected within the general formula of ABX₃ to produce a wide variety of perovskites 100, including, for example, methylammonium lead triiodide (CH₃NH₃PbI₃), and mixed halide perovskites such as CH₃NH₃PbI₃₋ₓClₓ, and CH₃NH₃₋ₓPbI₃₋ₓBrₓ. Thus, a perovskite 100 may have more than one halogen element, where the various halogen elements are present in non-integer quantities; e.g. x is not equal to 1, 2, or 3. In addition, perovskite halides, like other organic-inorganic perovskites, can form three-dimensional (3-D), two-dimensional (2-D), one-dimensional (1-D) or zero-dimensional (0-D) networks, possessing the same unit structure. As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the X-anion 130 of a perovskite 100 may include one or more anions, for example, one or more halogens (e.g. at least one of I, Br, Cl, and/or F), thiocyanate, and/or sulfur. Any combination is possible provided that the charges balance.

For example, a perovskite having the basic crystal structure illustrated in FIGS. 1A-1C, in at least one of a cubic, orthorhombic, and/or tetragonal structure, may have other compositions resulting from the combination of the cations having various valence states in addition to the 2+ state and/or 1+ state described above for lead and alkyl ammonium cations; e.g. compositions other than AB²⁺X₃ (where A is one or more cations, or for a mixed perovskite where A is two or more cations). Thus, the methods described herein may be utilized to create novel mixed cation materials having the composition of a double perovskite (elpasolites), A₂B¹⁺B³⁺X₆, with an example of such a composition being Cs₂BiAgCl₆ and Cs₂CuBiI₆. Another example of a composition covered within the scope of the present disclosure is described by A₂B⁴⁺X₆, for example Cs₂PbI₆ and Cs₂SnI₆. Yet another example is described by A₃B₂³⁺X₉, for example Cs₃Sb₂I₉. For each of these examples, A is one or more cations, or for a mixed perovskite, A is two or more cations.

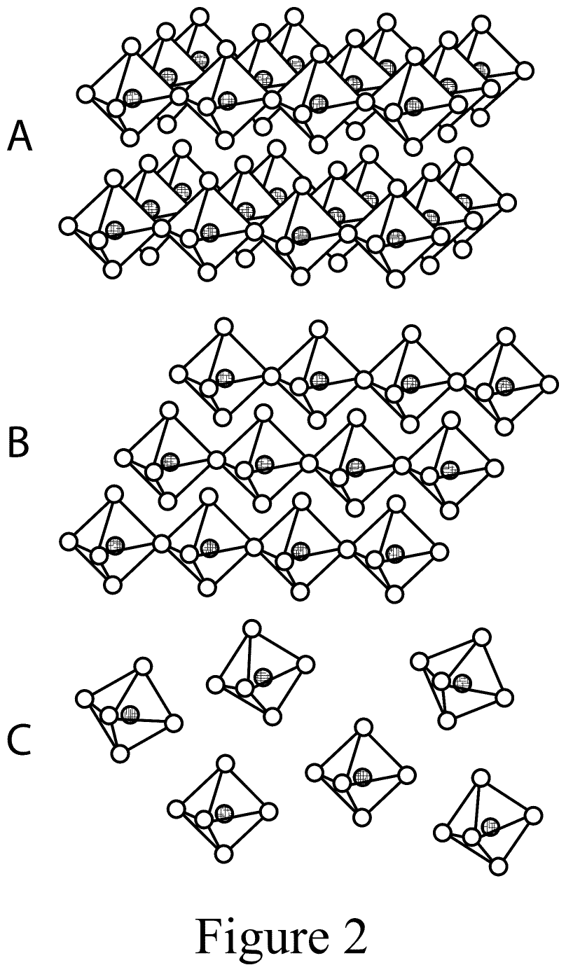

In addition, perovskite halides, like other organic-inorganic perovskites, can form a three-dimensional (3D) network, a two-dimensional (2D) network, a one-dimensional (1D) network and/or a zero-dimensional (0D) network, possessing the same unit structure. A perovskite's 3D network is illustrated in FIGS. 1A, 1B, and 1C. FIG. 2 illustrates a 2D perovskite network, a 1D perovskite network, and a 0D perovskite network, in Panels A, B, and C, respectively. As described above, a 3D perovskite may adopt a general chemical formula of ABX₃, in which the A-cation may be a monovalent cation (e.g. methylammonium and/or formamidinium CH(NH₂)₂²⁺), the B-cation may be a divalent cation (e.g. Pb²⁺ and/or Sn²⁺), and the X-anion may be a halide anion (I⁻, Br⁻, and/or Cl⁻). In this formula, the 3D network of perovskites may be constructed by linking all corner sharing BX₆ octahedra, with the A-cation filling the space between eight octahedral unit cells to balance the crystal charge.

Referring to Panel A of FIG. 2, through the chemically accomplished dimensional reduction of the 3D crystal lattice, 2D perovskites, (A′)ₘ(A)ₙ₋₁BₙX₃ₙ₊₁, may adopt a new structural and compositional dimension, A′ (not shown), where monovalent (m=2) or divalent (m=1) cations can intercalate between the X-anions of the 2D perovskite sheets. Referring to Panel B of FIG. 2, 1D perovskites are constructed by BX₆ octahedral chained segments spatially isolated from each other by surrounding bulky organic cations (not shown), leading to bulk assemblies of paralleled octahedral chains. Referring to Panel C of FIG. 2, typically, the 0D perovskites are constructed of isolated inorganic octahedral clusters and surrounded by small cations (not shown) which are connected via hydrogen bonding.

FIG. 3A compares the crystal structure of DMePDAPbI₄, an exemplary 2D perovskite with BDAPbI₄, another 2D perovskite. FIG. 3B illustrates a side view of the crystal structure of 2D DMcPDAPbI₄-1 and the corresponding hydrogen-bonding configuration, according to some embodiments of the present disclosure. FIG. 3C illustrates a side view of the crystal structure of 2D DMePDAPbI₄-2 and the corresponding hydrogen-bonding configuration, according to some embodiments of the present disclosure. These structures are discussed in more detail below.

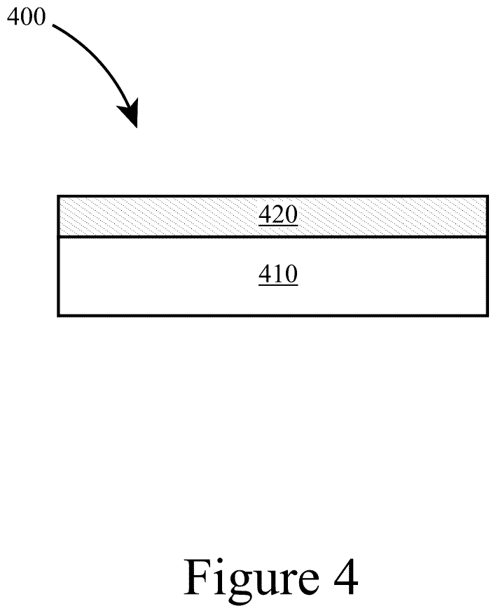

FIG. 4 illustrates a composition 400, according to some embodiments of the present disclosure. The composition 400 includes a first layer 410 of a first perovskite having a first crystalline structure and a second layer 420 a second perovskite having a second crystalline structure, where the first layer 410 and the second layer 420 are physically connected. In some embodiments of the present disclosure, the first crystalline structure may be substantially a 3-dimensional (3D) structure and the second crystalline structure may be substantially a 2-dimensional (2D) structure, as described above. As shown herein, such a composition may have at least one of a physical property or a performance metric that is improved when compared to a reference composition that is substantially the same as the composition shown in FIG. 4 but is absent the second layer.

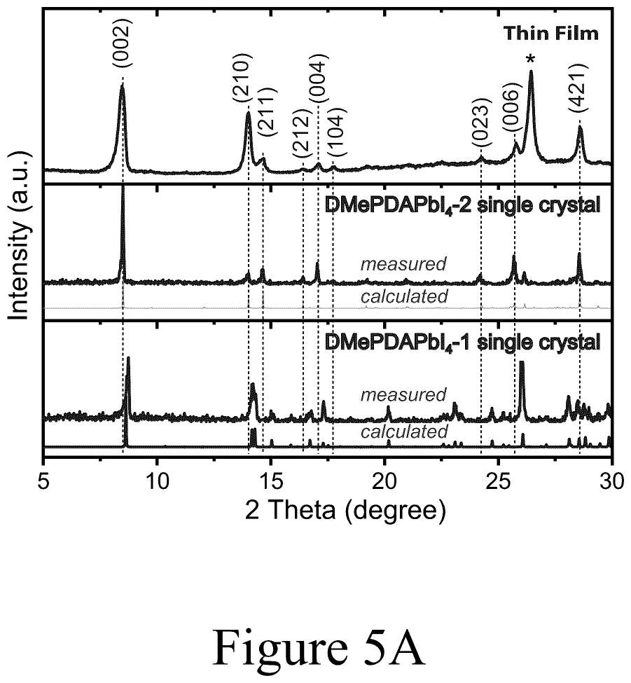

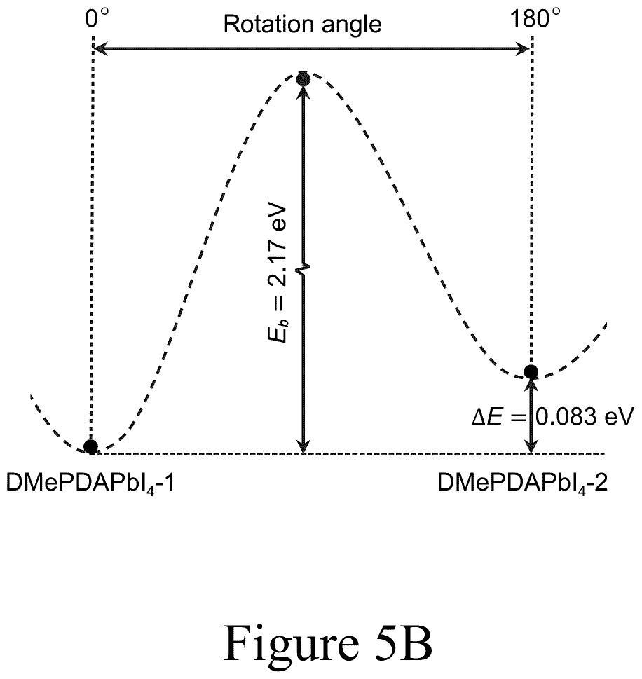

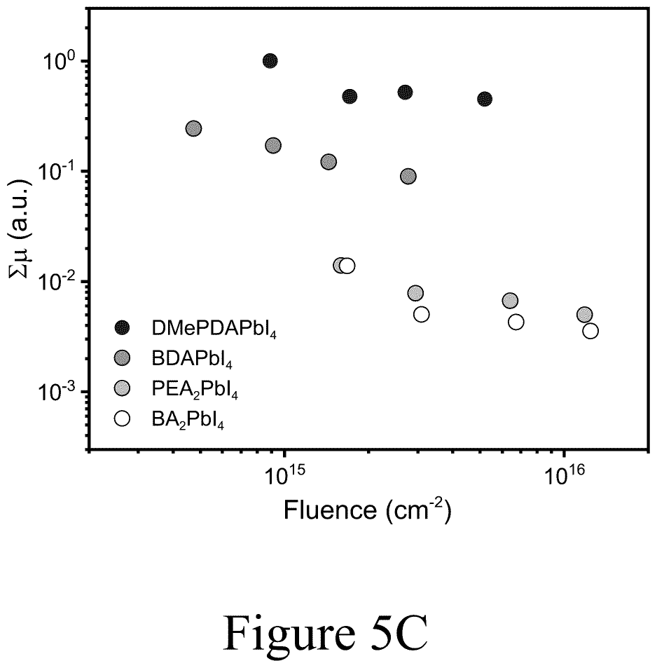

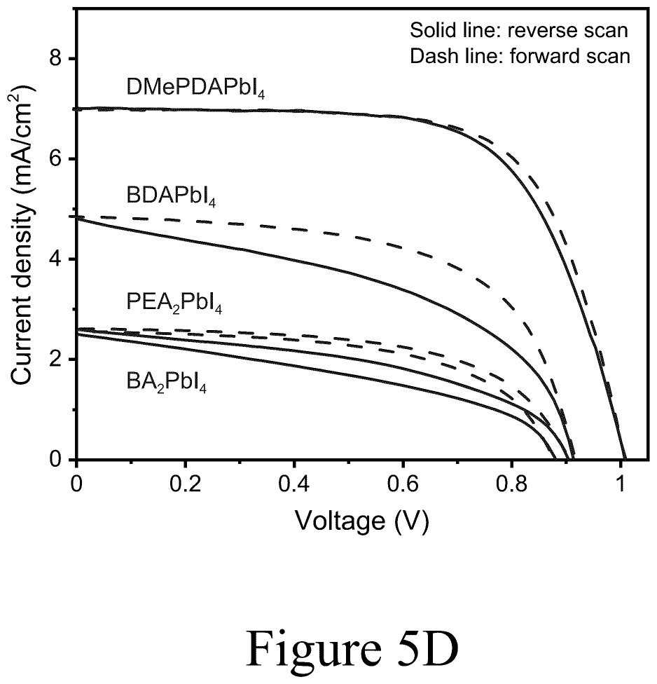

In some embodiments of the present disclosure, the first crystalline structure may have a composition defined by ABX₃, where A includes a first cation, B includes a second cation, and X includes an anion, as shown in FIGS. 1A, 1B, and 1C. In some embodiments of the present disclosure, the second crystalline structure may have a composition defined by A′BX₄ as shown in FIGS. 3A-3C, where A′ includes a third cation having a 2+ charge. In some embodiments of the present disclosure, A′ may have a characteristic length between about 2.53 Å and about 7.62 Å or between about 2.72 Å and about 7.06 Å. In some embodiments of the present disclosure, A′ may include a diammonium molecule, such as N,N-dimethyl-1,3-propane diammonium (DMePDA²⁺). In some embodiments of the present disclosure, the 2D structure may be as shown in Panel B of FIG. 3A as indicated by XRD as shown in FIG. 5A (DMePDAPbI₄-1). In some embodiments of the present disclosure, the 2D structure may be as shown in Panel C of FIG. 3A as indicated by XRD as shown in FIG. 5A (DMePDAPbI₄-2). The first layer 410 may have a thickness between about 100 nm and about 2000 nm. The second layer 420 may have a thickness between about 1 nm and about 100 nm.

In some embodiments of the present disclosure, the improved physical property and/or performance metric of the composition 400 having a second layer 420 may include at least one of an out-of-plane charge transport, a yield-mobility product, a smoother surface, a film roughness, a longer charge-carrier lifetime, a higher charge-carrier mobility, and/or a reduced surface-defect density. In some embodiments of the present disclosure, the root-mean-square of the film roughness may be less than or equal to about 16 nm. In some embodiments of the present disclosure, the yield mobility product (φΣμ) may be at least about 39.7 cm²/Vs. In some embodiments of the present disclosure, the charge-carrier lifetime may be at least about 1.32 microseconds. In some embodiments of the present disclosure, the out-of-plane charge transport of DMePDA-containing structures and/or compositions may be about (7-21)×10⁻² cm²V⁻¹s⁻¹.

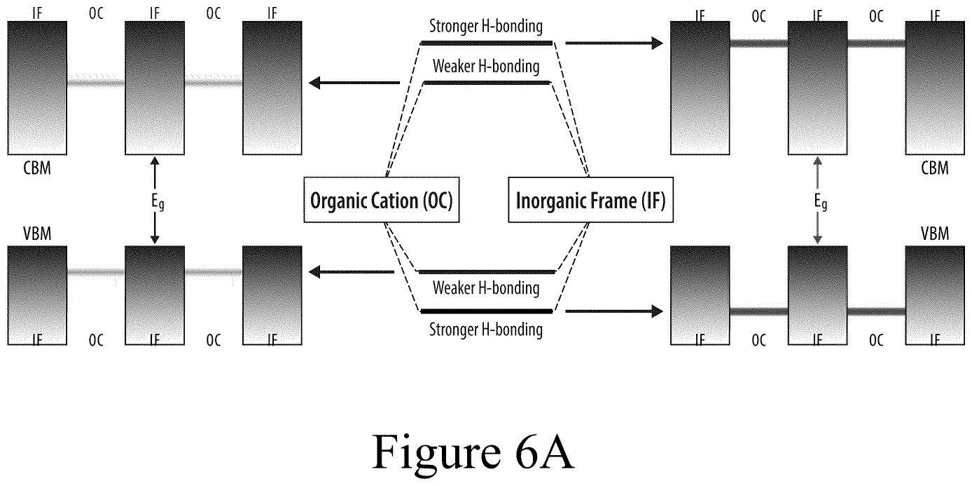

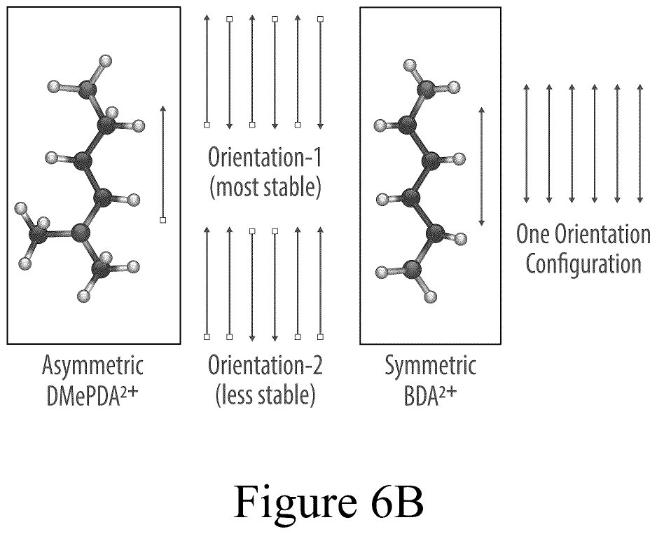

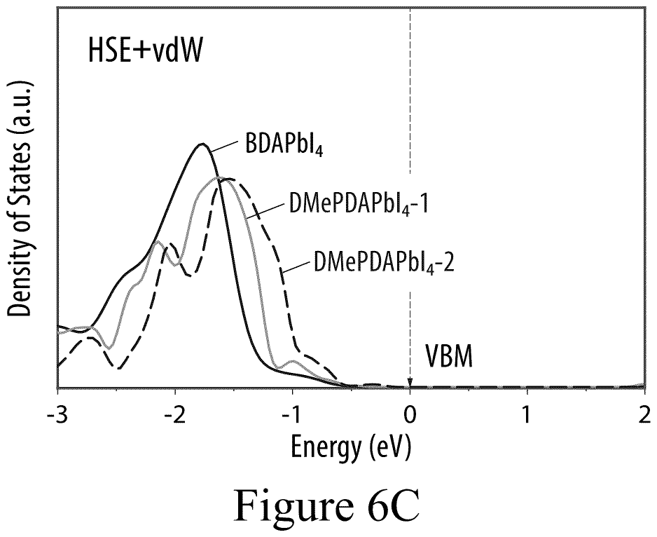

Thus, shown herein is a new rational design strategy to maximize the out-of-plane hole transport based on a metastable Dion-Jacobson (DJ) 2D perovskite surface layer with a reduced transport energy barrier by using asymmetric bulky organic molecules, leading to highly efficient and stable perovskite solar cells. The general design strategy to maximize the out-of-plane charge transport in 2D perovskites is illustrated in FIGS. 6A-6C.

Since the free electrons and holes are localized in the conduction band minimum (CBM) and valence band maximum (VBM) of the [PbI₆] planes, respectively, and due to the long distance between two adjacent [PbI₆] planes, the out-of-plane charge transport should go through the bulky cationic organic layers. Therefore, this charge transport is mainly limited by two factors: (1) the low carrier mobility of the bulky cationic organic layer; and (2) the energy barrier between the [PbI₆] planes and the bulky organic cations. To mitigate the first limit, DJ 2D structures based on a short and single layer of divalent organoammonium cations are generally more preferred than RP 2D structures based on double layers of monovalent organoammonium cations. To mitigate the second limiting factor, the band offsets between the [PbI₆] planes and the bulky cationic organic layers may be optimized. The coupling (interaction) between [PbI₆] planes and the organic cations may be through hydrogen bonding, and the change in the bonding strength can affect the band offsets. For a weaker hydrogen bonding configuration, the bonding states of the bulky organic layers are normally at higher energy position which brings them closer to the VBM of the [PbI₆] planes (see FIG. 6A); this can lead to a smaller band offset or barrier for hole transport between the [PbI₆] inorganic planes and organic cations. Due to the strong spin-orbital coupling of Pb 6p orbitals, the antibonding states of the organic layers are much higher than the CBM of the [PbI₆] planes. Therefore, a DJ structure with weaker hydrogen bonding can be expected to improve hole transport. A weaker hydrogen bonding (or H-bonding) configuration generally means a less stable structure. Thus, a metastable DJ 2D structure with short cationic organic layers could in principle facilitate out-of-plane hole transport.

The strategy described herein to induce the desired metastable H-bonding motifs in DJ 2D structures is to use asymmetric diammonium cations in lieu of symmetric straight chain divalent cations. FIG. 6B shows an example comparison between N,N-dimethyl-1,3-propane diammonium (DMePDA²⁺) and 1,4-butane diammonium (BDA²⁺). BDA²⁺ is symmetric and features two terminal primary ammonium ions on the butyl (C4) chain, whereas DMePDA²⁺ is asymmetric with a primary ammonium on one end and a dimethyl-substituted tertiary ammonium on the other end of the propyl (C3) chain. As shown in FIG. 6B, the “head or tail” H-bonding options for the DMePDA²⁺ molecules are asymmetric, giving rise to different possible relative orientations of the adjacent molecules. With different H-bonding interactions possible within two [PbI₆] planes, different energy polymorphs of the 2D structure can be expected. The most stable configuration and a less stable (or metastable) configuration are illustrated in FIG. 6B. The alternating relative head-to-tail alignment of adjacent DMePDA²⁺ cations (most stable orientation configuration) provide a larger compensation for overall structural relaxation than other orientation arrangements. In contrast, the symmetric BDA²⁺ molecule has only one possible orientation configuration and thus cannot form metastable polymorphs.

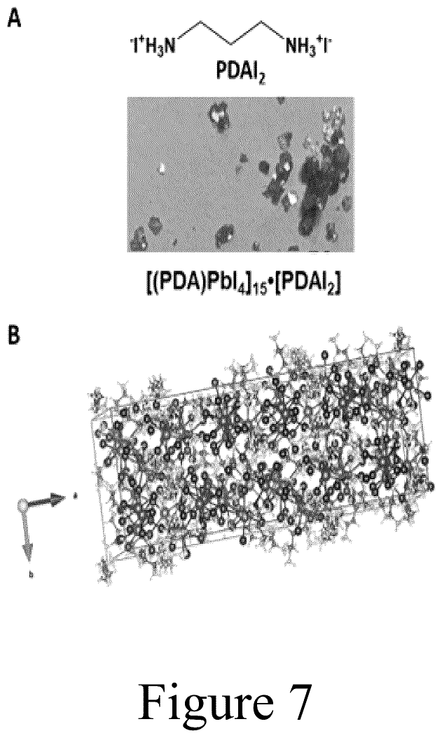

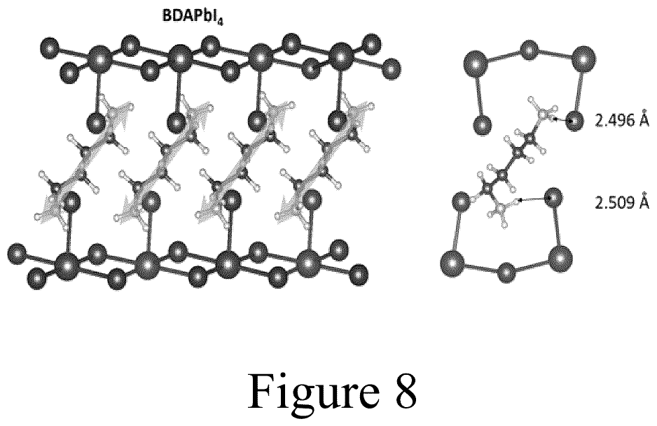

Single-crystal 2D DJ structures from BDAI₂ and DMePDAI₂ were examined and first-principle calculations conducted to verify our design strategy. It was found that 1,3-propane diammonium diiodine (PDAI₂) templated Pb—I to a non-perovskite structure (empirical formula: [PDAPbI₄]₁₅·[PDAI₂]) (see FIG. 7). Thus, BDA²⁺ represents the shortest linear-alkyl-chain diamine that forms an iodide-based 2D DJ structure (BDAPbI₄; see Panel A of FIG. 3A). Interestingly, C3-based DMePDAI₂ with two methyl groups attached to one side of PDA can form 2D DJ structures with two polymorphs, referred to as DMePDAPbI₄-1 (see Panel B of FIG. 3A) and DMePDAPbI₄-2 (see Panel C of FIG. 3A), respectively. The DMePDAPbI₄-1 single crystal, based on the most stable DMePDA²⁺ orientation alignment, was grown from a concentrated hydroiodic acid solution using a slow-crystallization process. In contrast, the DMePDAPbI₄-2 single crystal, based on a metastable orientational alignment, was formed from either a fast cooling or antisolvent quenching during single-crystal growth, both of which represent a fast-crystallization process. The average interlayer distances are comparable among these 2D structures (˜10.10-10.39 Å), with that of BDAPbI₄ being the shortest. The corresponding hydrogen-bonding configurations for these three single-crystal structures (see FIG. 8 and FIGS. 3B and 3C) are consistent with FIG. 6B.

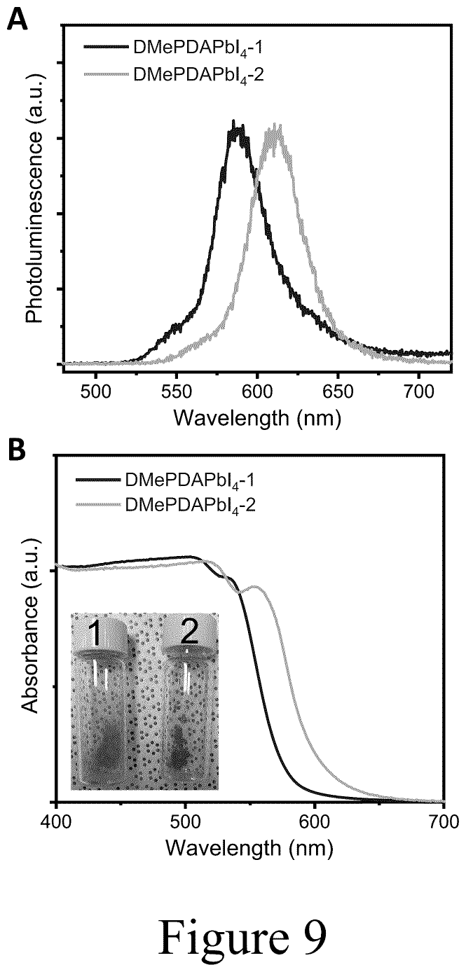

The DMePDAPbI₄-1 single crystal was grown, based on the most stable DMePDA²⁺ orientation alignment, from a concentrated hydroiodic acid solution using a slow-crystallization process as adapted from our previous report. In contrast, the DMePDAPbI₄-2 single crystal, based on a metastable orientational alignment, was formed from either a fast cooling or antisolvent quenching during single-crystal growth, both of which represent a fast-crystallization process. In comparison to DMePDAPbI₄-1, DMePDAPbI₄-2 had an emission wavelength that was ˜25-nm red-shifted, which is consistent with the corresponding absorption data (see FIG. 9). The average interlayer distances were comparable among these 2D structures (˜10.10 to 10.39 Å), with that of BDAPbI₄ being the shortest.

The design strategy described above was confirmed by density functional theory (DFT) calculation. The effect of organic molecules was calculated by using the screened hybrid functional and van der Waals (vdW) interaction (HSE+vdW). The DMePDAPbI₄-2 structure is indeed less stable than the DMePDAPbI₄-1 structure. The energy level differences of the organic cations in BDAPbI₄, DMePDAPbI₄-1, and DMePDAPbI₄-2 are clearly seen in the total density of states (DOSs) of the organic cations (i.e., the sum of states of C, N, and H atoms) as shown in FIG. 6C. The total DOS of BDA²⁺ cations in BDAPbI₄ is lower in energy (farther from VBM) than that of DMePDA²⁺ cations in DMePDAPbI₄-1, which in turn is lower in energy compared with the total DOS of DMePDA²⁺ cations in DMePDAPbI₄-2. Thus, the out-of-plane hole transport is expected to improve from BDAPbI₄ to DMePDAPbI₄-2.

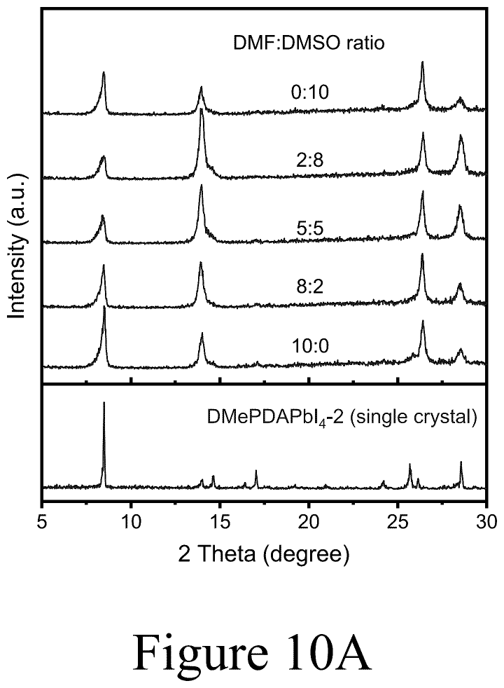

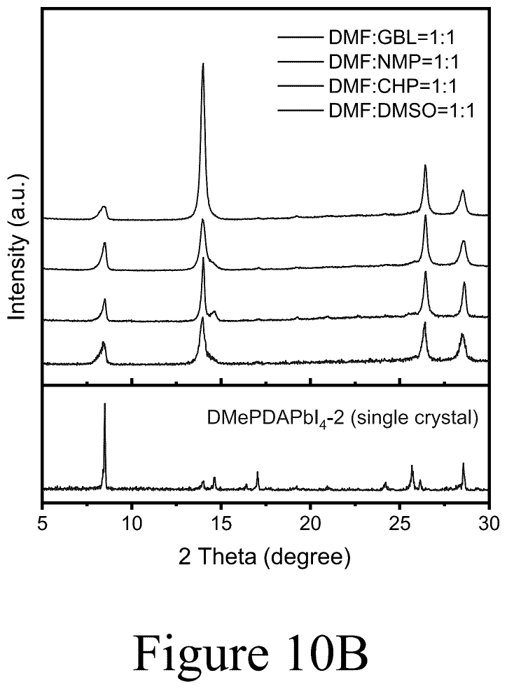

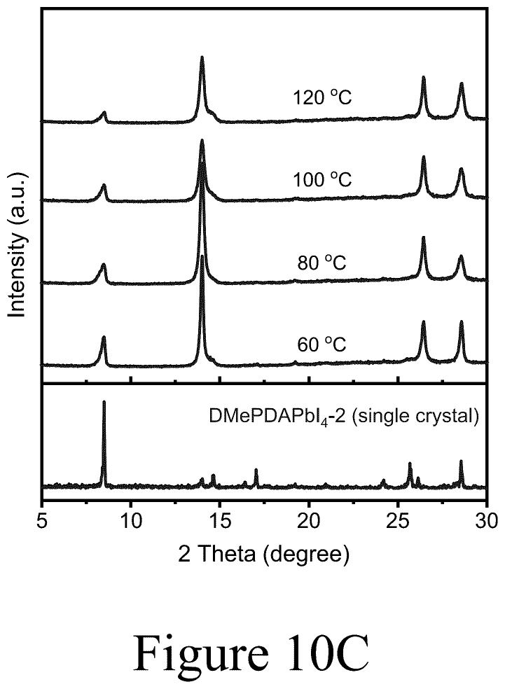

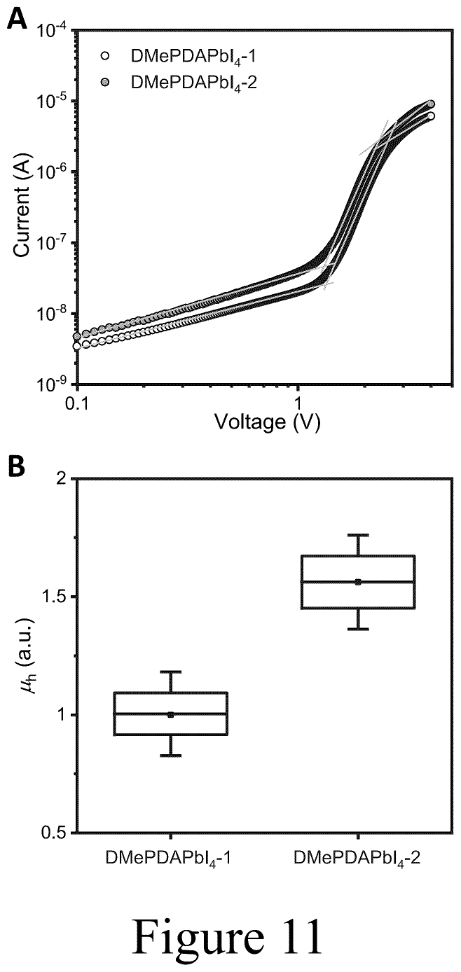

The rapid perovskite layer growth condition from standard solution deposition also leads to the formation of the metastable DMePDAPbI₄-2 structure. FIG. 5A shows the XRD patterns of the DMePDAPbI₄ layer prepared by spin coating. The calculated powder XRD patterns based on DMePDAPbI₄-1 and DMePDAPbI₄-2 single-crystal structures are shown for comparison. The layer XRD pattern matches well with that of the DMePDAPbI₄-2 structure. Note that a metastable polymorph does not mean it is unstable. The phase transformation between polymorphs requires 180-degree rotation of the alkyl chain, which is highly energetically unfavorable (see FIG. 5B), suggesting that the polymorphs can be kinetically trapped into a local minimum that is stable under most operation conditions. A wide range of layer growth conditions from solution all formed DMePDAPbI₄-2 layers (see FIGS. 10A-10C).

To test the hypothesis that the reduced energy barrier from the asymmetric bulky organic cation layer can facilitate charge transport between inorganic [PbI₆] sheets, time-resolved microwave conductivity (TRMC) measurements along the out-of-plane direction were conducted. FIG. 5C compares the TRMC results from several n=1 2D perovskite layers calibrated by their corresponding internal quantum yield of charges measured in devices. The out-of-plane transport for DMePDAPbI₄ (or more specifically DMePDAPbI₄-2) is about a factor of 4-5 faster than that of BDAPbI₄ despite the slightly longer interlayer distance. Space-charge-limited current (SCLC) measurements further verified that the DMePDAPbI₄-2 structure had faster out-of-plane hole transport than the DMePDAPbI₄-1 structure (see FIG. 11). These results confirmed the role of reducing the energy barrier for improving out-of-plane charge transport. This confirms the significance of reducing the energy barrier for improving out-of-plane charge transport. Note that the out-of-plane transport for the two 2D DJ structures (DMcPDAPbI₄ and BDAPbI₄) are significantly faster than those of the two 2D RP structures (BA₂PbI₄ and PEA₂PbI₄). These TRMC results are consistent with the J-V results of PSCs based on the corresponding n=1 2D structures (see FIG. 5D and Table 1); the DMePDAPbI₄-based PSC reached a PCE of 4.90%, which is the highest obtained thus far for any n=1 2D lead-iodide-based PSCs.

TABLE 1
Performance parameters of perovskite solar cells based on
perovskite layers of different bulky cations (n = 1)
under different scan directions with a bias step of 10 mV. (V_{oc}:
open-circuit voltage; J_{sc}: short-circuit current density;
FF: fill factor; PCE: power conversion efficiency).

| | | J_{sc} | V_{oc} | | PCE |
|---|---|---|---|---|---|
| Device | Scan | (mA/cm²) | (V) | FF | (%) |
| DMePDAPbI₄ | Forward | 6.98 | 1.01 | 0.69 | 4.90 |
| | Reverse | 7.01 | 1.01 | 0.66 | 4.33 |
| BDAPbI₄ | Forward | 4.85 | 0.91 | 0.61 | 2.69 |
| | Reverse | 4.81 | 0.92 | 0.47 | 2.08 |
| PEA₂PbI₄ | Forward | 2.61 | 0.91 | 0.59 | 1.40 |
| | Reverse | 2.60 | 0.90 | 0.46 | 1.07 |
| BA₂PbI₄ | Forward | 2.56 | 0.88 | 0.57 | 1.28 |
| | Reverse | 2.50 | 0.88 | 0.41 | 0.90 |

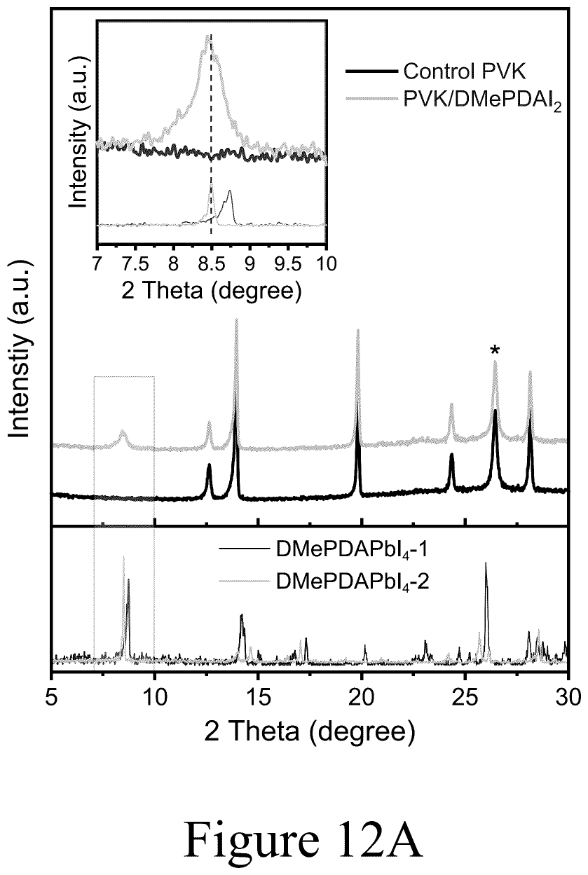

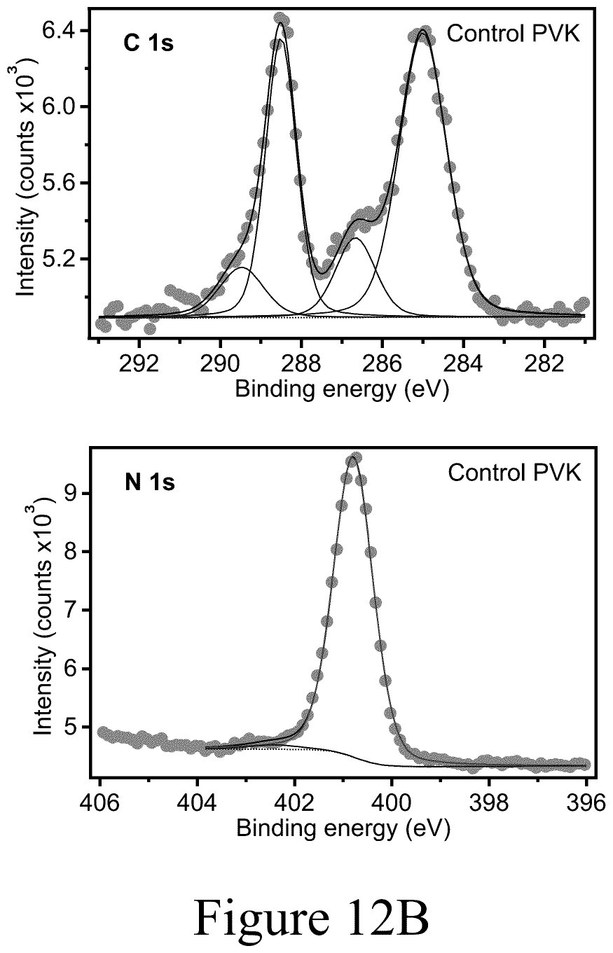

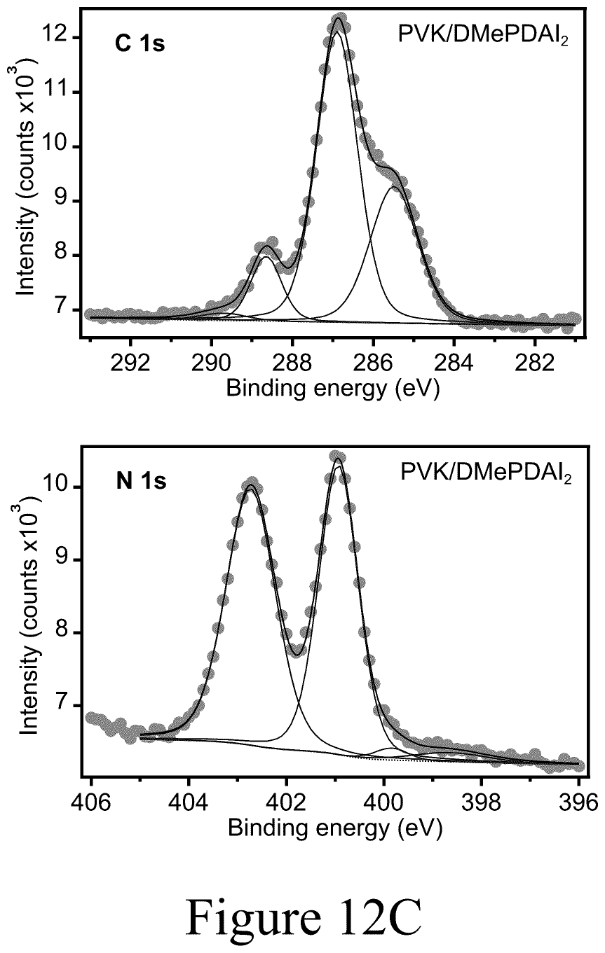

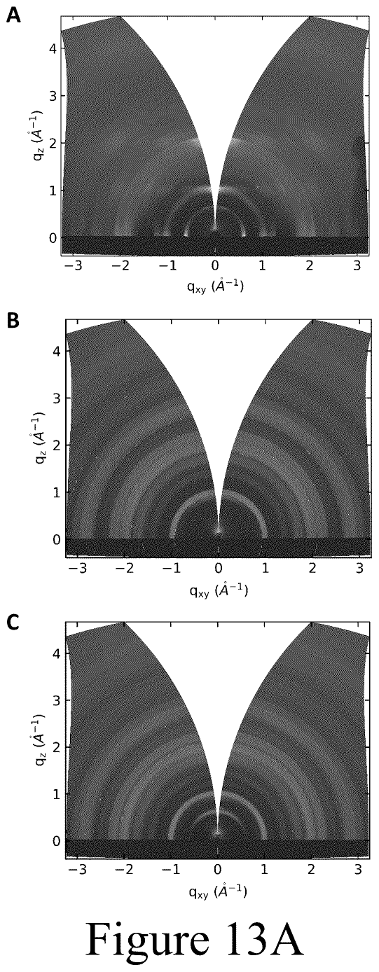

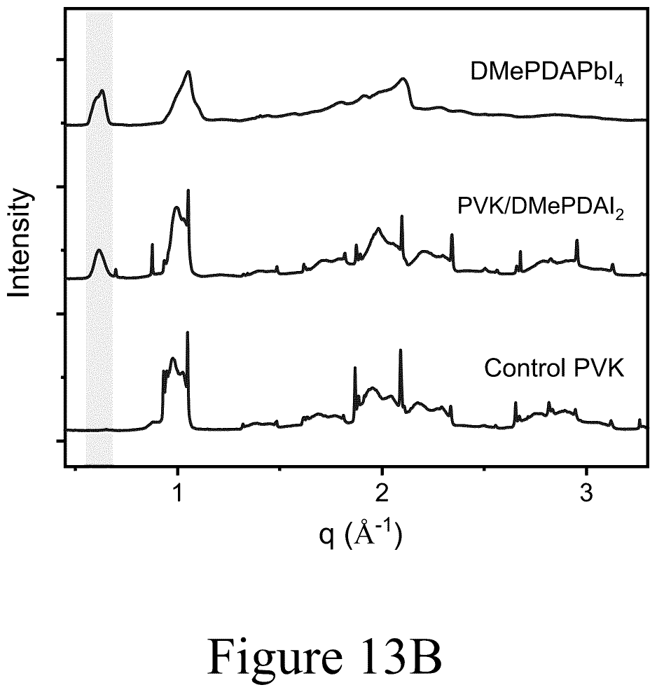

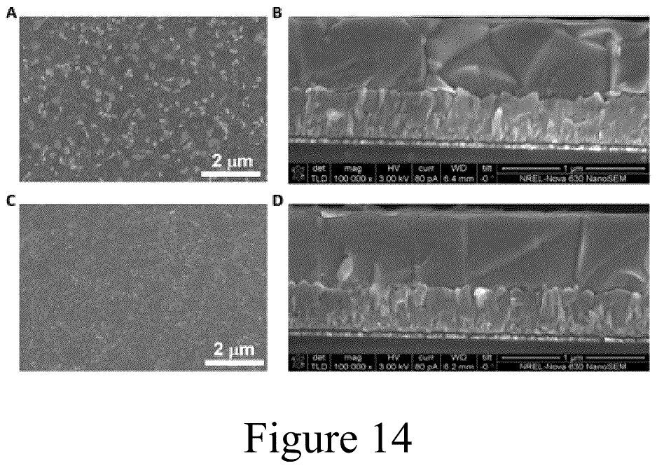

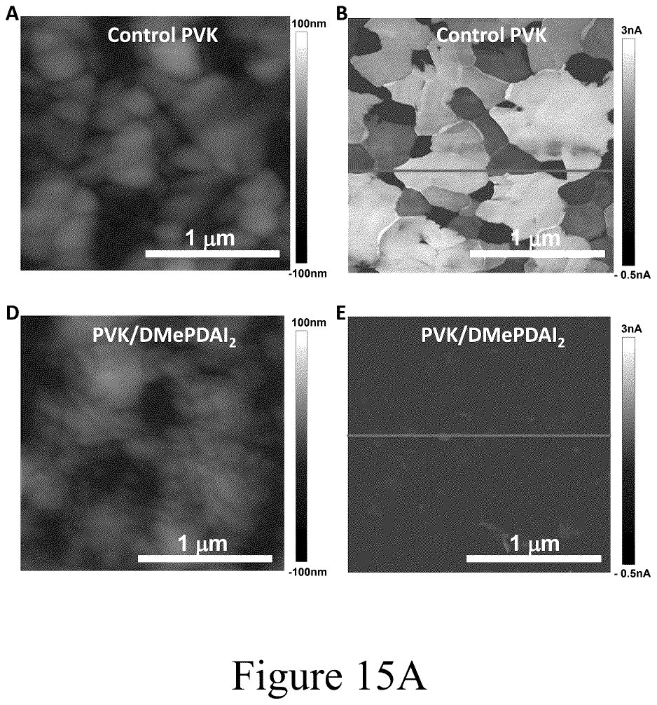

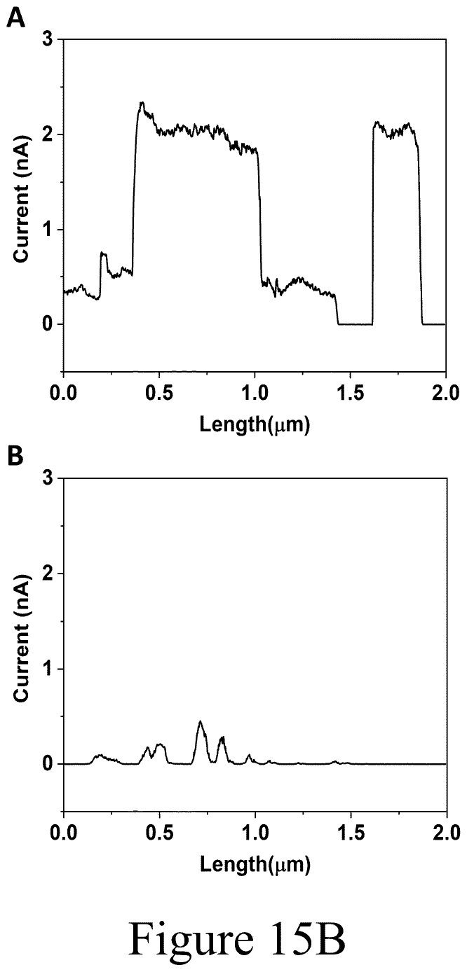

Next, the impact of this metastable design motif with the use of DMePDAPbI₄ as a surface layer to improve the quality of 3D perovskite absorbers was determined. A general solution approach was use, spin coating the corresponding bulky organic halide salt in isopropanol (IPA) solution on top of a 3D perovskite absorber layer. Specifically, the DMePDAI₂/IPA solution was coated on 3D perovskite layers of (FAPbI₃)_{0.85}(MAPbI₂Br)_{0.1}(CsPbI₃)_{0.05} (i.e., FA_{0.85}MA_{0.1}Cs_{0.05}PbI_{2.9}Br_{0.1}) followed by annealing. The XRD results suggest the formation of the DMePDAPbI₄-2 structure, as evidenced by the characteristic low-angle diffraction peak at ˜8.5° (see FIG. 12A). Note that the excess PbI₂ (at ˜12.6°) in the control film was also reduced with the DMePDAI₂ treatment. The low-angle diffraction peak associated with the 2D structure from the XRD results are further confirmed by the GIWAXS measurement (see FIGS. 13A and 13B). The scanning electron microscopy (SEM) measurements indicate that the treatment induced formation of a thin surface layer with small apparent grain sizes (see FIG. 14). The conductive-atomic force microscopy (C-AFM) measurements show that the current of the treated film is much more uniform and lower than the control film, which is consistent with the formation of a capping layer (see FIGS. 15A and 15B).

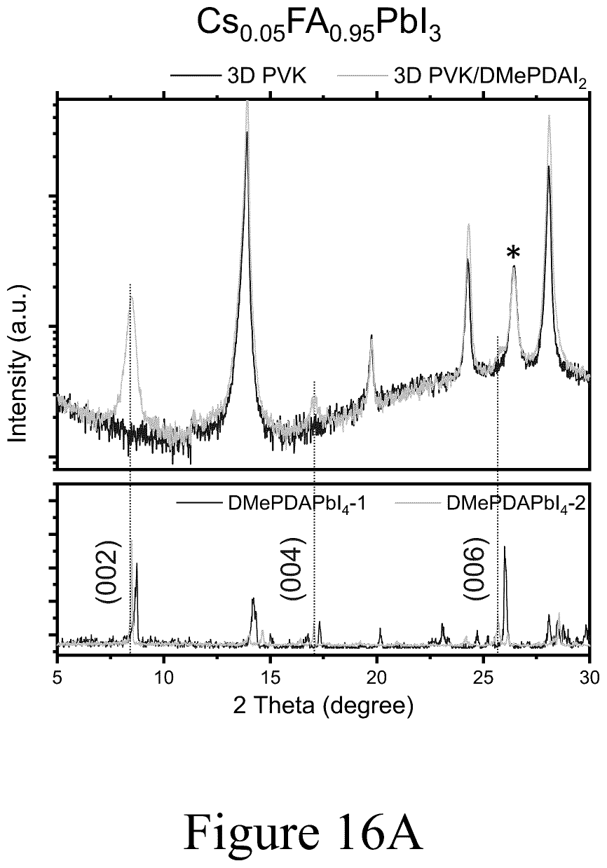

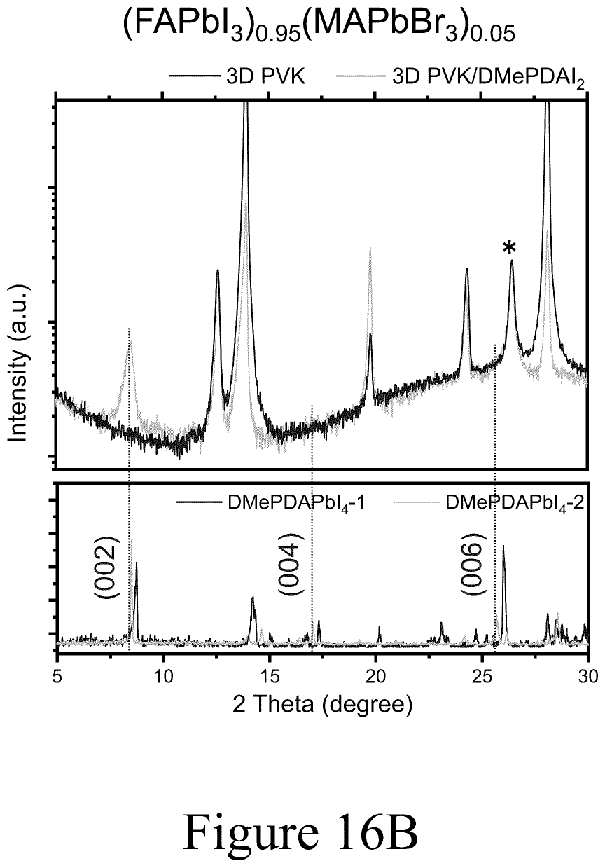

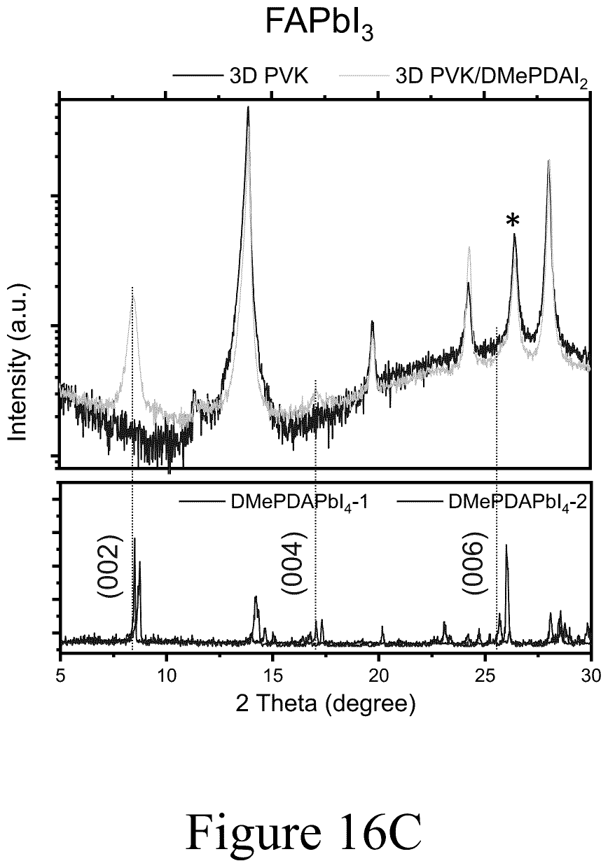

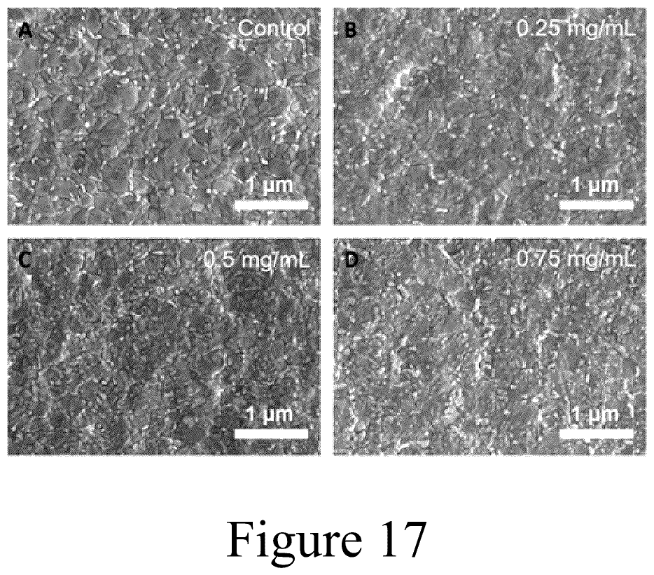

We also checked the 2D structures on top of three other common perovskite compositions of Cs_{0.05}FA_{0.95}PbI₃, (FAPbI₃)_{0.95}(MAPbBr₃)_{0.05}, and FAPbI₃ (see FIGS. 16A, 16B, and 16C, respectively). For these compositions, the characteristics peaks at (002), (004), and (006) matched well to DMePDAPbI₄-2, which were absent in the DMePDAPbI₄-1 spectrum. Finally, the low-angle diffraction peak associated with the 2D structure from the XRD results were further confirmed by grazing-incidence wide-angle x-ray scattering (GIWAXS) measurements (see FIG. 13). In terms of 2D surface layer topology and coverage, the scanning electron microscopy (SEM) measurements indicated that the treatment induced formation of a thin surface layer with small apparent grain sizes (see FIG. 14 and FIG. 17). The conductive-atomic force microscopy (C-AFM) measurements show that the current of the treated layer is much more uniform and lower than the control layer, which is consistent with the formation of a capping layer over the 3D perovskite layer (see FIG. 15).

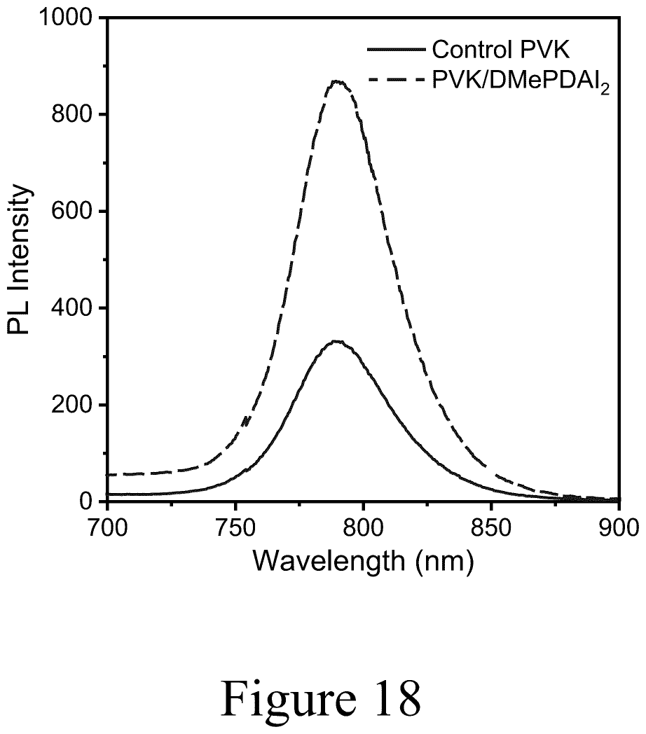

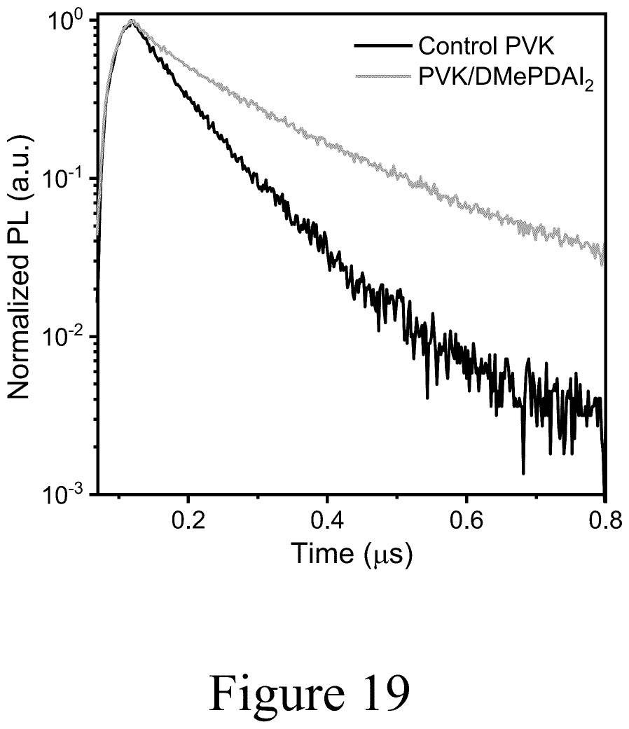

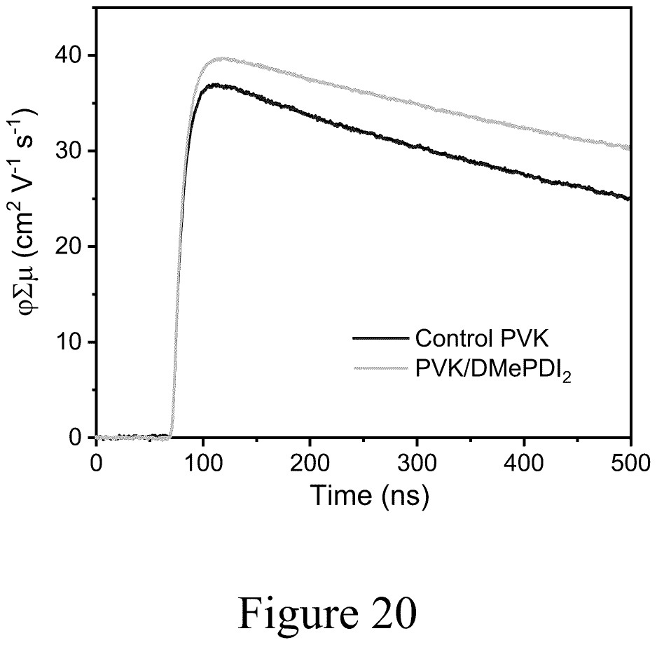

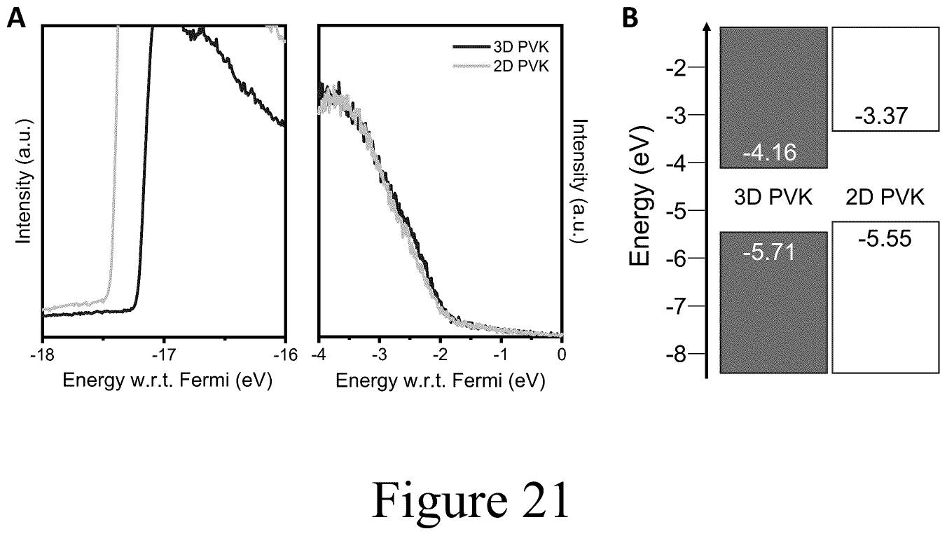

To gain more insight into how the DMePDAI₂ modification affects the optoelectronic properties in perovskite layers, steady-state photoluminescence (PL), time-resolved photoluminescence (TRPL), and TRMC studies were conducted on these samples. The DMePDAI₂ treatment leads to enhanced PL intensity (see FIG. 18), longer TRPL lifetime (see FIG. 19 and Table 2), and improved TRMC mobility and lifetime (see FIG. 20), which are consistent with the improved surface properties. In addition, the ultraviolet photoelectron spectroscopy (UPS) measurements showed that the 2D surface treatment improved the energetics for hole transport from the 3D perovskite to the 2D surface layer (see FIG. 21).

TABLE 2
Lifetimes of the control, and DMePDAI₂-modified
perovskite layers extracted by fitting the PL decay
curve with a bi-exponential decay function.

| Samples | fast component τ₁ (ns) | slow component τ₂ (ns) |
|---|---|---|
| Control | 50 | 101 |
| DMePDAI₂ | 61 | 181 |

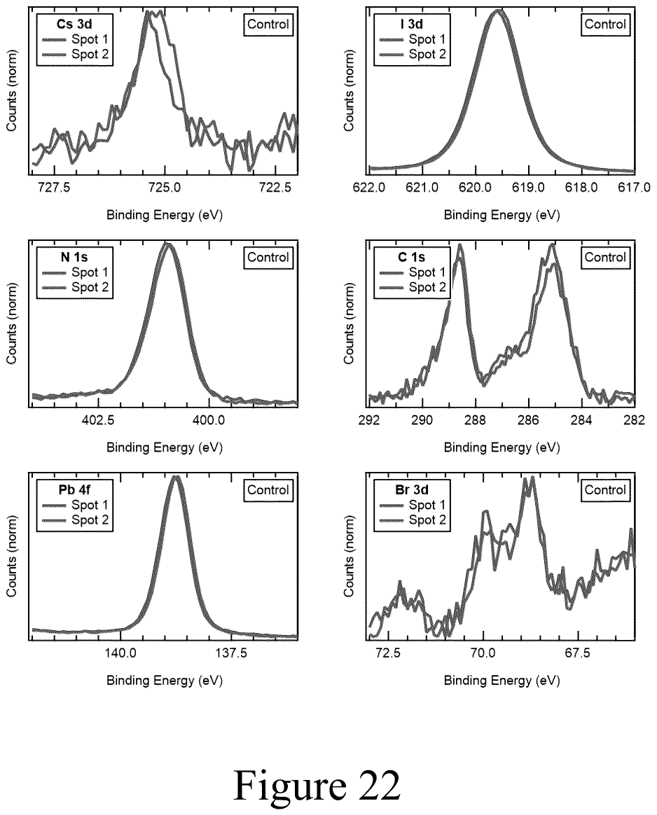

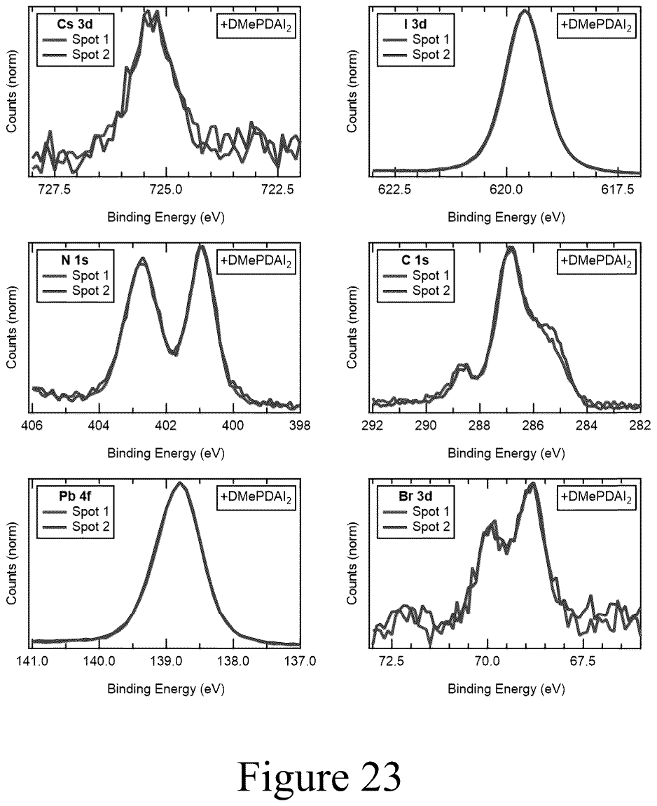

The impact of the DMePDAI₂ treatment on the perovskite surface chemistry was investigated by X-ray Photoelectron Spectroscopy (XPS) measurements. Normalized core levels from key elements identified on the sample surface are included in FIGS. 22 and 23. The spectral shapes of most core levels show minimal change between the two samples, indicating similar bonding environments. However, surface treatment caused significant changes in the C 1s and N 1s core levels. To highlight these changes, the core levels were fit (see FIGS. 12B and 12C) using constrained fitting procedures that are summarized in Tables 3 and 4. Results indicate that the control sample has a N 1s region whose relative peak areas are dominated by a C═NH₂⁺ (FA) peak (˜401 eV) with a small shoulder to higher binding energy (˜403 eV) that corresponds to C—NH₃ (MA). The DMePDAI₂ treatment increased the area of the C—NH₃ peak while creating two additional peaks at lower binding energy consistent with C—NH₂ (˜400 eV) and the tertiary amine in DMePDAI₂ (˜398 eV). Concomitant with these changes, a significant redistribution is observed of the features in the C 1s spectra comprising of four main peaks that are consistent with primarily C—C/C—H (˜285 eV), N—CH₃ (˜287 eV), HC(NH₂)₂ (˜289 eV), and C—O/C═O bonds (˜290 eV). The surface treatment decreases the concentration of HC(NH₂)₂ bonds from FA on the surface while simultaneously increasing the amount of N—CH₃ and C—C/C—H bonds. In addition, XPS reveals that surface treatment increases the amount of halide on the surface, from about 2.6 halide-to-lead ratio for the control to 3.1 for the DMePDAI₂-treated layer. Collectively, these results suggest that both the organic and halide regions of the additive are incorporated into the top surface of the treated layers. Moreover, since undercoordinated lead is known to cause donor defects on the surface, resulting in downwards band bending and increased recombination centers, the increase in the halide-to-lead ratio associated with the formation of 2D interfacial component upon surface treatment is consistent with a less defective surface.

TABLE 3
The constrained fitting procedure (from low binding energy
[BE] to high) used by deconvoluted C1s peak.

| Peak # | BE location | FWHM |
|---|---|---|
| C—C/C—H | −1.7 to −1.4 | 1.3-1.4 |
| C—NH₃ | x | 1.15-1.25 |
| HC(NH₂) | +1.75 to +1.85 | 0.9-1.1 |
| C—O/C═O | +2.75 to +2.85 | 1.25-1.35 |

TABLE 4
The constrained fitting procedure (from low binding energy
[BE] to high) used by deconvoluted N1s peak.

| Peak # | BE location | FWHM |
|---|---|---|
| CH₂—NH⁺—(CH₃)₂ | −2.35 to −2.25 | 1.8-2.0 |
| C—NH₂ | −1.2 to −1.1 | 0.8-1.0 |
| C═NH₂⁺ | x | 0.95-1.0 |
| C—NH₃ | +1.6 to +1.8 | 1.15-1.25 |

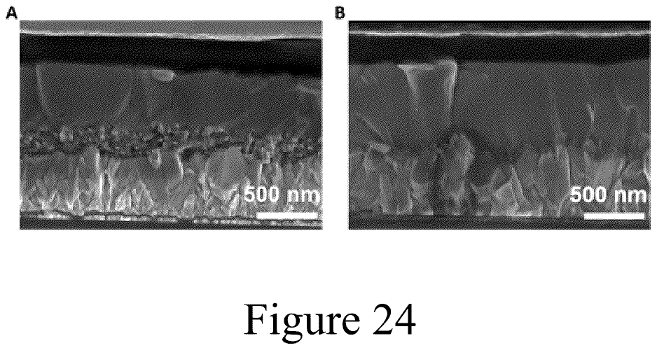

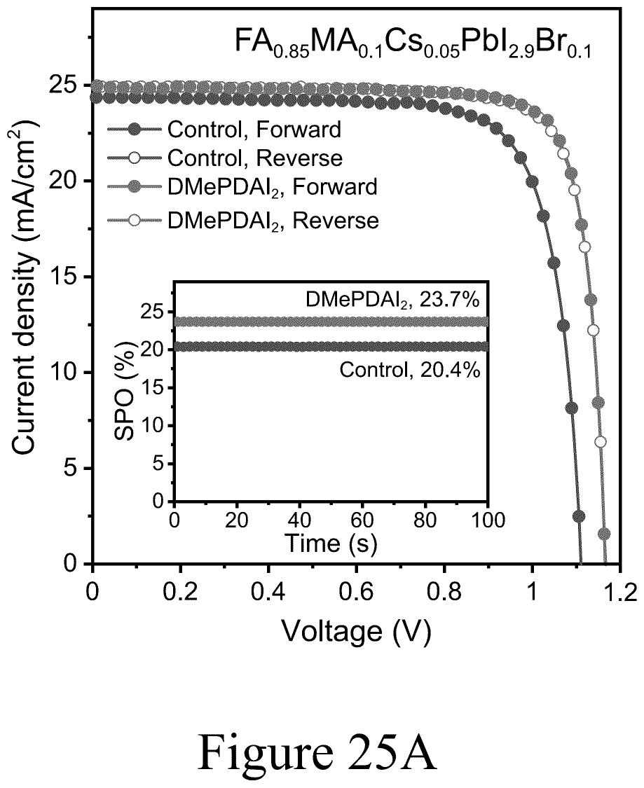

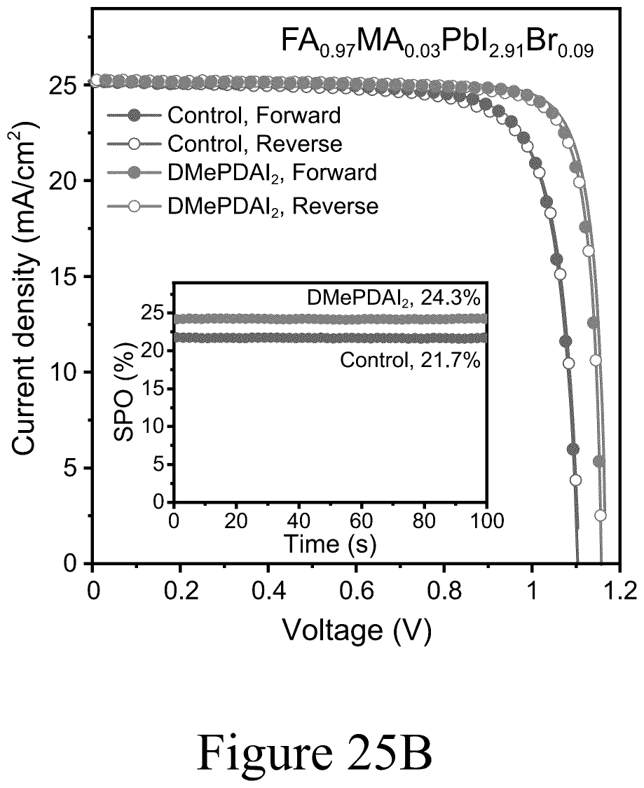

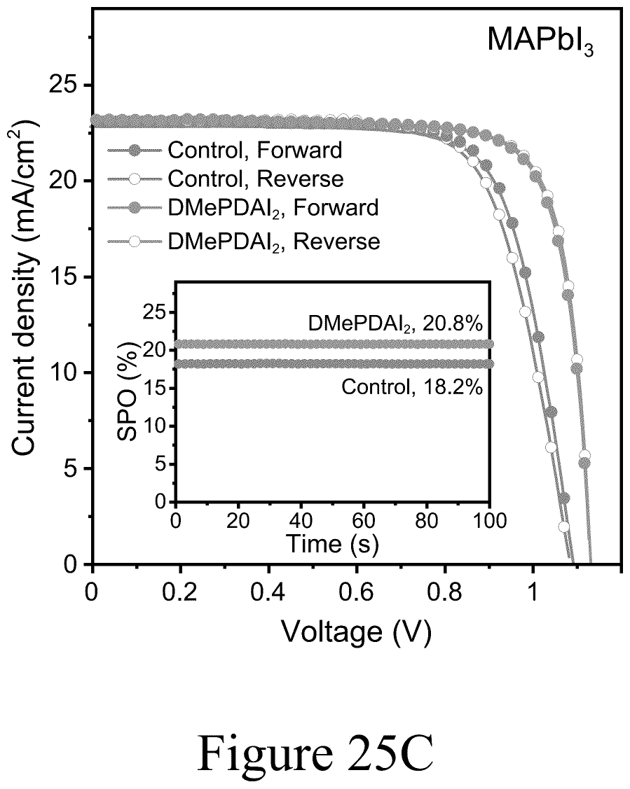

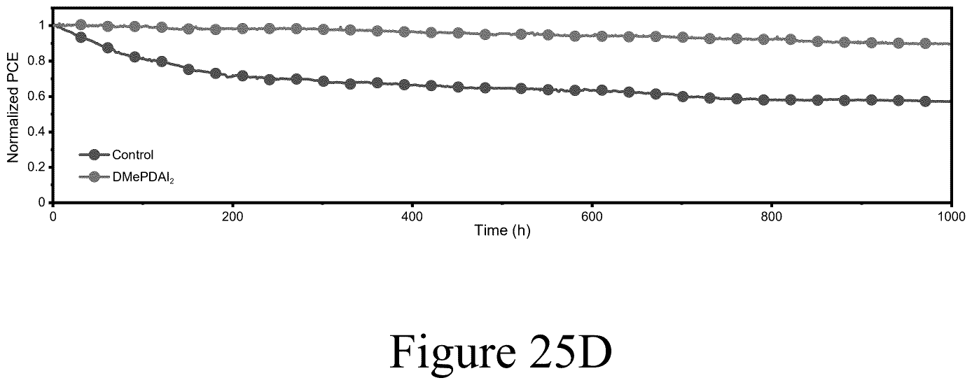

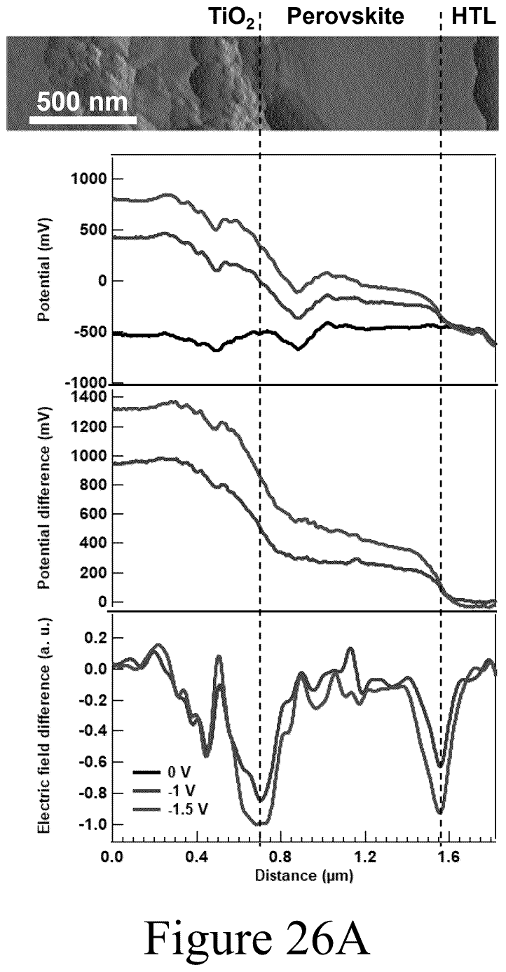

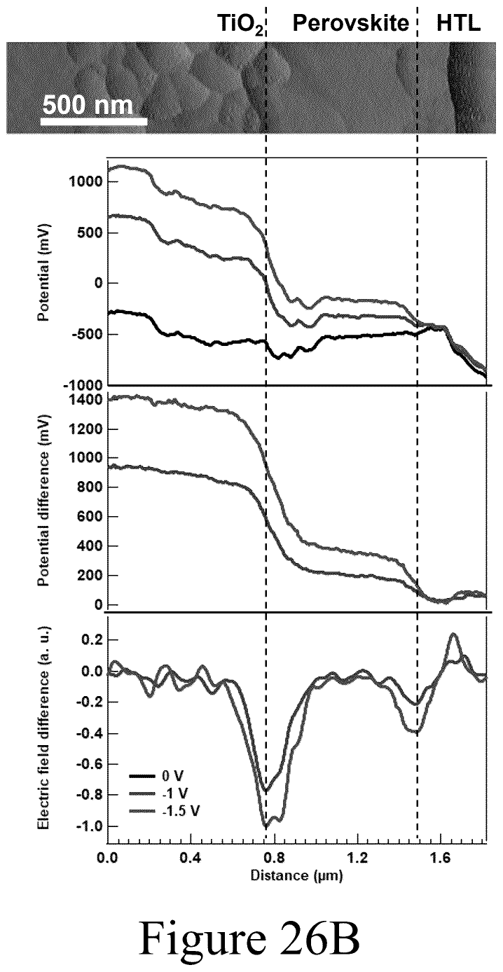

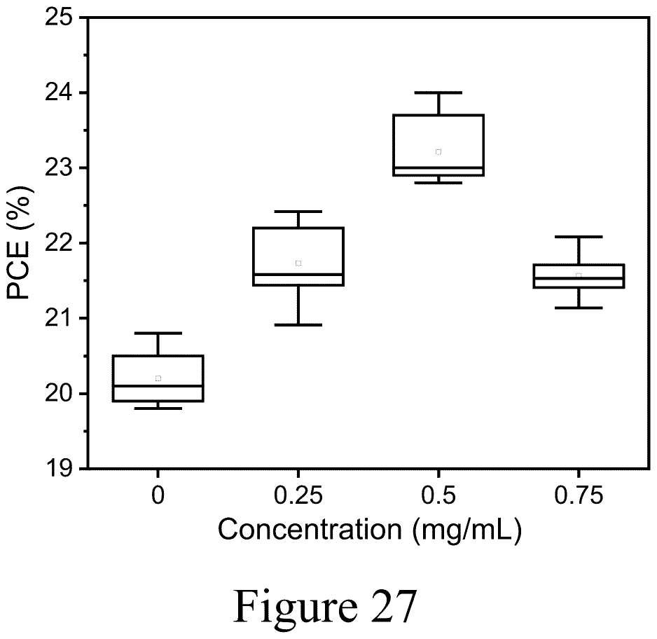

To investigate the impact of DMePDAI₂ surface treatment on the PV performance, PSCs using a standard n-i-p device architecture, glass/FTO/ETL/perovskite/HTL/Au where fabricated, where ETL is TiO₂ or SnO₂, and HTL is spiro-OMeTAD, with more details in the experimental section. Typical cross-section SEM images of devices are shown in FIG. 24. FIG. 25A compares the J-V curves of the PSCs based on triple-cation-mixed-halide FA_{0.85}MA_{0.1}Cs_{0.05}PbI_{2.9}Br_{0.1} without and with DMePDAI₂ treatment under simulated 100-mW/cm² AM1.5G illumination. The corresponding PV parameters are summarized in Table 5. With the surface treatment, the device PCE is significantly increased from about 20.91% to 23.95% from forward scan and from 20.42% to 23.68% from reverse scan. The PCE improvement is also consistent with a better perovskite/HTL junction based on the cross-sectional Kelvin probe force microscopy (KPFM) measurements (see FIGS. 26A and 26B). Note that the optimum concentration for DMePDAI₂-surface treatment was found at 0.5 mg/mL (see FIG. 27).

TABLE 5
PV parameters of PSCs based on control and DMePDAI₂-modified
perovskite layers using different perovskite compositions.

| | | J_{sc} | V_{oc} | | PCE | SPO |
|---|---|---|---|---|---|---|
| Device | Scan | (mA/cm²) | (V) | FF | (%) | (%) |
| FA_{0.85}MA_{0.1}Cs_{0.05}PbI_{2.9}Br_{0.1} | Forward | 24.35 | 1.111 | 0.773 | 20.91 | 20.4 |
| | Reverse | 24.32 | 1.099 | 0.764 | 20.42 | |
| FA_{0.85}MA_{0.1}Cs_{0.05}PbI_{2.9}Br_{0.1}/ | Forward | 24.97 | 1.167 | 0.822 | 23.95 | 23.7 |
| DMePDAI₂ | Reverse | 24.93 | 1.167 | 0.814 | 23.68 | |
| FA_{0.97}MA_{0.03}PbI_{2.91}Br_{0.09} | Forward | 25.21 | 1.103 | 0.791 | 21.98 | 21.7 |
| | Reverse | 25.15 | 1.108 | 0.781 | 21.78 | |
| FA_{0.97}MA_{0.03}PbI_{2.91}Br_{0.09}/ | Forward | 25.25 | 1.158 | 0.843 | 24.65 | 24.3 |
| DMePDAI₂ | Reverse | 25.26 | 1.158 | 0.839 | 24.54 | |
| MAPbI₃ | Forward | 23.09 | 1.090 | 0.742 | 18.67 | 18.2 |
| | Reverse | 23.09 | 1.080 | 0.729 | 18.18 | |
| MAPbI₃/DMePDAI₂ | Forward | 23.19 | 1.131 | 0.797 | 20.90 | 20.8 |
| | Reverse | 23.19 | 1.132 | 0.794 | 20.84 | |

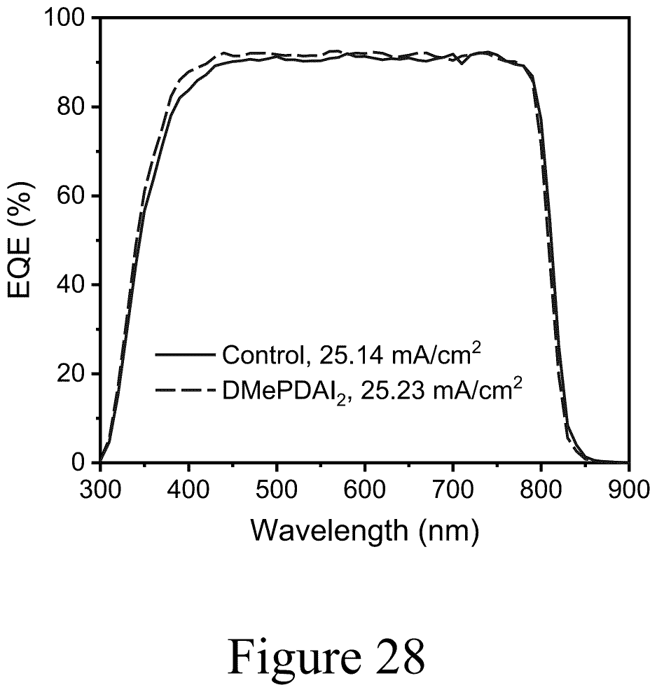

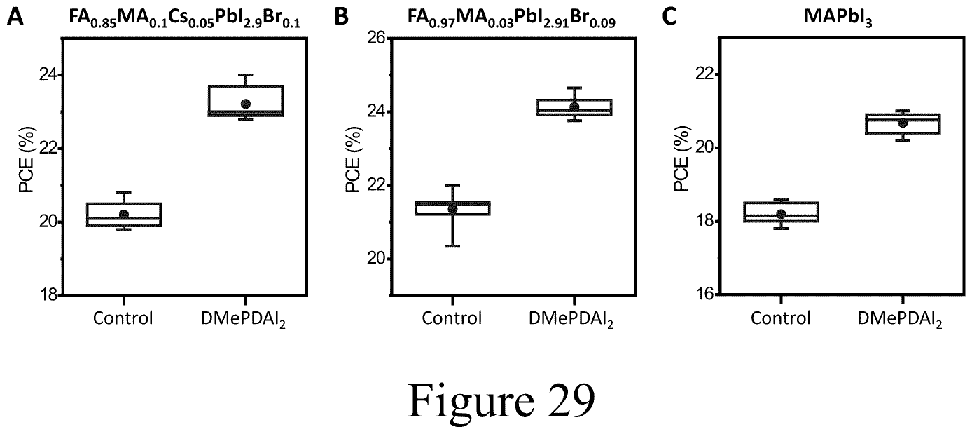

In addition to the FAMACs-based perovskite composition, the impact of DMePDAI₂ surface treatment on PSCs was examined based on double-cation-mixed-halide (FA_{0.97}MA_{0.03}PbI_{2.91}Br_{0.09}) and single-cation-single-halide (MAPbI₃), using ETL of SnO₂ and TiO₂, respectively. Significant device PCE improvement was also observed for both compositions (see FIGS. 25B and 25C). Noteworthy for PSCs based on FA_{0.97}MA_{0.03}PbI_{2.91}Br_{0.09}, the PCE was improved from 21.98% to 24.65% from forward scan and from 21.78% to 24.54% from reverse scan, with J_{sc} over 25 mA/cm², which is in agreement with the EQE spectrum (see FIG. 28). For all three perovskite compositions, the stabilized power outputs (SPOs) for PSCs based on the control and DMePDAI₂-modified perovskite layers match well with the J-V measurements (insets of FIGS. 25A-25C and Table 5). The PCE improvement for all three perovskite compositions is reproducible based on the statistical comparison (see FIG. 29).

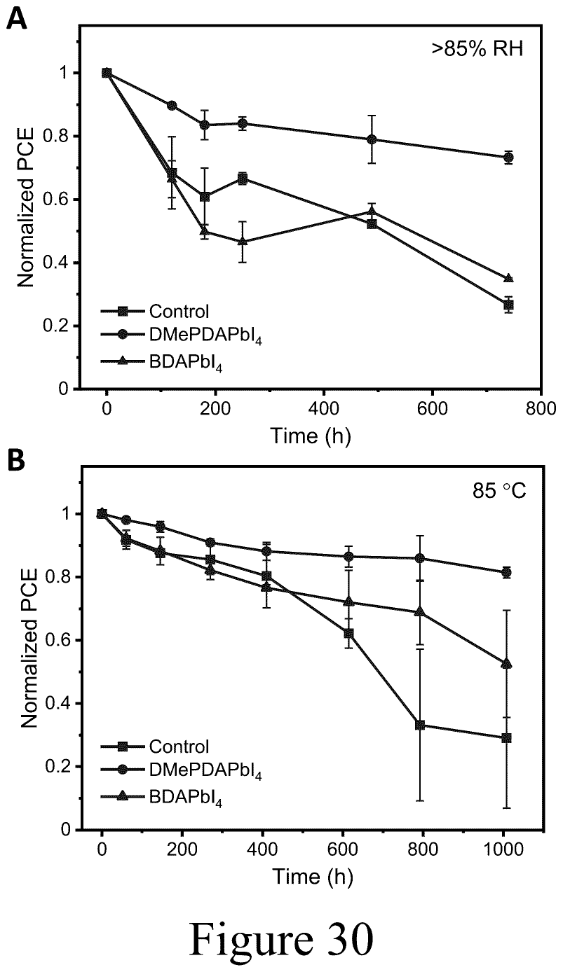

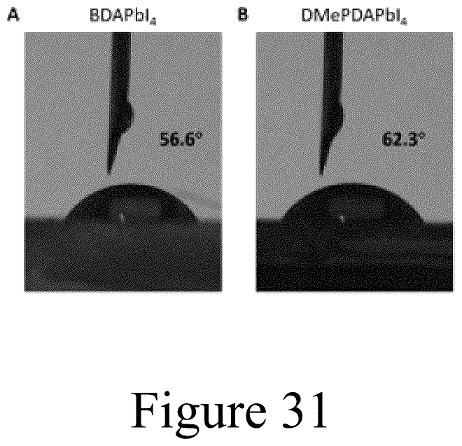

Finally, the operation stability of unencapsulated FA_{0.85}MA_{0.1}Cs_{0.05}PbI_{2.9}Br_{0.1}-based PSCs using maximum power point (MPP) tracking at ˜40° C. in N₂ was checked, following the ISOS-L-1 stability protocol. FIG. 25D shows that the DMePDAI₂-modified PSC showed only 10% relative efficiency drop after 1000 h continuous operation whereas the PCE of the control device decreased by about 43%. The stability improvement with DMePDAI₂ surface treatment was also observed when the devices were tested at high moisture (>85% relative humidity) or high temperature (85° C.) conditions (see FIGS. 30 and 31). These results suggests that the DMPDAI₂-modification to form a 2D DJ phase surface layer is a general way to improve PSC performance. The use of the metastable—but kinetically stable—2D DJ structures, as described herein, through hydrogen bonding tuning based on asymmetric bulky organic molecules represents a promising new chemical design of perovskite interfacial engineering for enhancing PSC efficiency and stability.

### Experimental

Materials: Lead oxide (PbO, 99.999%), 1,3-propanediamine, N,N-dimethyl-1,3-propane diamine, N,N-anhydrous dimethylformamide (DMF), ethanol, 2-propanol (IPA), chlorobenzene (CB), dimethyl sulfoxide (DMSO) and 57% aqueous hydriodic acid (HI) solution (99.95%, distilled, stabilized by H₃PO₂) were purchased from Sigma-Aldrich and used as-received without any other refinement unless otherwise specified. Formamidinium iodide (FAI), methylammonium bromide (MABr), methylammonium chloride (MACI), and 1,4-butane diammonium iodide (BDAI₂) were purchased from Greatcell Solar. Lead iodide (PbI₂) and lead bromide (PbBr₂) were from TCI Corporation. 2,2′,7,7′-Tetrakis[N,N-di(4-methoxyphenyl)amino]-9,9′-spirobifluorene (spiro-OMeTAD) was received from Merck Corporation. The titanium diisopropoxide bis(acetylacetonate), bis(trifluoromethanesulfonyl)imide lithium salt, tert-butylpyridine, and cesium iodide (CsI) were purchased from Sigma-Aldrich. Substrates are patterned fluorine-doped tin-oxide-coated glass (<15 Ω/square) obtained from Advanced Election Technology Co., Ltd.

Synthesis of 1,3-propane diammonium diiodine (PDAI₂) and N,N-dimethyl-1,3-propane diammonium diiodide (DMePDAI₂): 5 mL of 1,3-propanediamine or N,N-dimethyl-1,3-propane diamine was first mixed with 15 mL ethanol (200 Proof), and the solution was placed in an ice water bath (0° C.). 20 mL HI solution was slowly added to the PDA solution (dropwise). The mixture was allowed to stir for 2 hours. After the reaction, solvents were removed by vacuum and white powders were collected by vacuum filtration. The product was recrystallized from ethanol/diethyl ether and dried in vacuum overnight. DMePDAI₂ was synthesized following the same process.

Synthesis of [PDAPbI₄]₁₅·[PDAI₂] single crystals: 335 mg (1.5 mmol) of PbO and 492 mg (1.5 mmol) of PDAI₂ were fully dissolved in 6 mL of HI solution at 90° C. The solution was then slowly cooled to room temperature at a rate of 1° C./h, giving yellow crystals. The crystals were then isolated from the parent solution by vacuum filtration and dried under vacuum.

Synthesis of (BDA) PbI₄ single crystals: 335 mg (1.5 mmol) of PbO and 516 mg (1.5 mmol) of BDAI₂ were fully dissolved in 6 mL of HI solution at 90° C. The solution was then slowly cooled to room temperature at a rate of 1° C./h, giving yellow crystals. The crystals were then isolated from the parent solution by vacuum filtration and dried under vacuum.

Synthesis of (DMePDA) PbI₄-1 single crystals: 335 mg (1.5 mmol) of PbO and 537 mg (1.5 mmol) of DMePDAI₂ were fully dissolved in 6 mL of HI solution at 90° C. The solution was then slowly cooled to room temperature at a rate of 1° C./h, giving red sheet-like crystals. The crystals were then isolated from the parent solution by vacuum filtration and dried under vacuum.

2D (n=1) perovskites-based device fabrication: Devices were prepared on conductive fluorine-doped tin oxide (FTO)-coated glass substrates. The substrates were cleaned extensively by deionized water, acetone, and isopropanol. A compact titanium dioxide (TiO₂) layer about 40 nm thick was deposited by spray pyrolysis of 7 mL of 2-propanol solution containing 0.6 mL of titanium diisopropoxide bis(acetylacetonate) solution (75% in 2-propanol, Sigma-Aldrich) and 0.4 mL of acetylacetone at 450° C. in air. The precursor solutions were prepared by mixing PbI₂ and BDAI₂ or DMePDAI₂, and PEAI or BAI at a stoichiometric ratio of 1:1 and 1:2, respectively, with a concentration of 0.25 mol/L in DMF. The spin-coating procedure was performed at 4,000 rpm for 30 s. Thereafter, the substrate was put onto a hotplate for 15 min at 100° C. Subsequently, the hole-transporting layer (HTM) was deposited on the top of the perovskite by spin coating at 4,000 rpm for 15 s. The spiro-OMeTAD solutions were prepared by dissolving the spiro-OMeTAD in 1-mL chlorobenzene at a concentration of 77.6 mg/mL, with the addition of 20.6 μL bis(trifluoromethanesulfonyl)imide lithium salt from a stock solution in acetonitrile, 35.5 μL of tert-butylpyridine. The fabrication of perovskite layer and HTM layer of devices were executed in a dry air box, where the variation of humidity is from about 1% to 4%, the variation of temperature is from about 20° C. to 24° C. The devices were finalized by thermal evaporation of 100-nm gold.

(FAPbI₃)_{0.85}(MAPbI₂Br)_{0.1}(CsPbI₃)_{0.05}-based device fabrication: Devices were prepared on conductive fluorine-doped tin oxide (FTO)-coated glass substrates. The substrates were cleaned extensively by deionized water, acetone, and isopropanol. A compact titanium dioxide (TiO₂) layer of about 40 nm was deposited by spray pyrolysis of 9-mL ethanol solution containing 0.6-mL titanium diisopropoxide bis(acetylacetonate) solution (75% in 2-propanol, Sigma-Aldrich) and 0.4-mL acetylacetone at 450° C. in air. On top of this layer, mesoporous titanium dioxide was formed by spin-coating 30-nm-sized nanoparticles (Dyesol 30NRD, Dyesol) diluted in ethanol (1:5.5 w/w) at 4,500 rpm for 15 s. The (FAPbI₃)_{0.85}(MAPbI₂Br)_{0.1}(CsPbI₃)_{0.05} precursor solution was prepared in a glovebox from a 1.60 M Pb²⁺ with 5% excess of PbI₂ and in the mixed solvent of DMF and DMSO; the volume ratio of DMF/DMSO was 4:1. The spin-coating procedure was performed at 2,000 rpm for 10 s followed by 6,000 rpm for 30 s. At 15 s before the last spin-coating step, 140 μL of chlorobenzene were pipetted onto the substrate. Thereafter, the substrate was put onto a hotplate for 20 minutes at 120° C.; these are identified as the “control” samples. For DMePDAI₂ treatment, different concentrations of DMePDAI₂ were dissolved in IPA and spin-coated on the surface of the perovskite at 3000 rpm for 30 s with subsequent annealing for 2 mins at 100° C. The best condition is designated “DMePDAI₂” samples. Subsequently, the hole-transporting layer (HTM) was deposited on top of the perovskite by spin coating at 4,500 rpm for 15 s. The spiro-OMeTAD solutions were prepared by dissolving the spiro-OMeTAD in 1-mL chlorobenzene at a concentration of 77.6 mg/mL, with the addition of 20.6 μL bis(trifluoromethanesulfonyl)imide lithium salt from a stock solution in acetonitrile, 35.5 μL of tert-butylpyridine. The devices were finalized by thermal evaporation of 100-nm gold.

FA_{0.97}MA_{0.03}PbI_{2.91}Br_{0.09}-based device fabrication: FTO glass substrates were washed by ultrasonication in water with detergent, clean water, and 2-propanol sequentially. The SnO₂ electron transport layer was deposited using the chemical bath deposition method, and the resulting sample was annealed at 150° C. for 2 h. The perovskite precursor solution was prepared by mixing 1.55 M PbI₂, 1.55 M FAI 0.048 M MAPbBr₃ and 0.5 M MACI in a mixed solvent (DMF/DMSO=8:1). Then the perovskite precursor solution was deposited onto the UV-ozone treated SnO₂ layer at 5000 rpm for 20s, where 1 mL of diethyl ether was dropped on the rotating layer 10 s after spinning. The resulting layer was annealed at 150° C. for 15 min and 100° C. for 5 min, sequentially. For DMePDAI₂ treatment, 200 μL of 0.5 mg/ml DMePDAI₂ in IPA was spin-coated on perovskite layer at 3000 rpm for 30 s with subsequent annealing for 2 mins at 100° C. The spiro-OMeTAD layer was deposited on the perovskite layer by spin coating the spiro-OMeTAD stock solution at 4000 rpm for 30 s. Finally, a 100 nm Au electrode layer was deposited by thermal evaporation.

MAPbI₃-based device fabrication: Devices were prepared on conductive fluorine-doped tin oxide (FTO)-coated glass substrates. The substrates were cleaned extensively by deionized water, acetone, and isopropanol. A compact titanium dioxide (TiO₂) layer of about 40 nm was deposited by spray pyrolysis of 9-mL ethanol solution containing 0.6-mL titanium diisopropoxide bis(acetylacetonate) solution (75% in 2-propanol, Sigma-Aldrich) and 0.4-mL acetylacetone at 450° C. in air. On top of this layer, mesoporous titanium dioxide was formed by spin-coating 30-nm-sized nanoparticles (Dyesol 30NRD, Dyesol) diluted in ethanol (1:5.5 w/w) at 4,500 rpm for 15 s. The MAPbI₃ precursor solution was prepared in a glovebox from a 1.45 M Pb²⁺ with 5% excess of PbI₂ and in the mixed solvent of DMF and DMSO; the volume ratio of DMF/DMSO was 4:1. The spin-coating procedure was performed at 2,000 rpm for 10 s followed with 6,000 rpm for 30 s. At 15 s before the last spin-coating step, 140 μL of chlorobenzene were pipetted onto the substrate. Thereafter, the substrate was put onto a hotplate for 30 minutes at 100° C. For DMePDAI₂ treatment, the 200 μL of 0.5 mg/ml DMePDAI₂ in IPA was spin-coated onto the perovskite layer at 3000 rpm for 30 s with subsequent annealing for 2 mins at 100° C. Subsequently, the hole-transporting layer (HTM) was deposited on top of the perovskite by spin coating at 4,500 rpm for 15 s. The devices were finalized by thermal evaporation of 100-nm gold.

Perovskite layer and device characterizations: SEM (FEI Nova 630, field-emission gun) imaging was performed with an electron-beam voltage of 3 kV in the immersion-lens mode. The XRD of the perovskite layers was characterized using a Rigaku D-Max 2200 diffractometer with Cu Kα radiation. The optical absorption spectra of perovskite layers were measured using an ultraviolet/visible (UV/Vis) spectrophotometer (Cary6000i). Solar cell performance measurements were taken under a simulated AM 1.5G illumination (100 mW/cm², Oriel Sol3A Class AAA Solar Simulator). The photocurrent density-voltage (J-V) characteristics were measured using a Keithley 2400 source meter. The J-V curves of all devices were measured by masking the active area with a metal mask of area 0.12 cm². Both backward-scan and forward-scan curves were measured with a bias step of 10 mV and delay time of 0.05 s. The continuous current and power output were measured using a potentiostat (Princeton Applied Research, Versa STAT MC). External quantum efficiency (EQE) spectra of solar cells were measured using a solar cell quantum-efficiency measurement system (QEX10, PV Measurements). Single-crystal structure analysis via X-ray diffraction (XRD) was performed on a Bruker D8 Venture Photon 2 diffractometer at the University of Kentucky and at the ALS on a Bruker D8 Photon 100 diffractometer. Stability measurements were performed with maximum power-point (MPP) tracking under continuous illumination from a full AM1.5 sun-equivalent white LED lamp in N₂ at about 40° C.

GIWAXS characterization: GIWAXS data were collected at beamline 11-3 at the Stanford Synchrotron Radiation Source (SSRL) at the SLAC National Accelerator Laboratory. The X-ray photon energy used at this beamline is 12.7 keV. Samples were exposed to the beam for 60 s in a sealed chamber under helium flow in grazing incidence geometry at an incident angle in the range of 0.12°-3.12°. A Rayonix MX225 CCD area detector was placed at a sample-to-detector distance of 200 mm. Collected data was calibrated against a reference sample (LaB₆) using a software package pyFAI. The same python package was used for the data processing

$$q = \frac{4 π}{λ} sin ( \frac{2 θ}{2} ) .$$

The integration was performed between 0°<χ<90°, where x is the azimuthal angle.

KPFM and C-AFM characterizations: The measurements were performed inside an Ar-filled glovebox with water and oxygen level lower than 0.01 ppm. All the scans were collected via Nanosensor PPP-EFM tips. The KPFM mappings have a spatial resolution of 30 nm and an electrical resolution of 10 mV. We directly cleaved the cells inside the glovebox with no exposure to air or polishing/ion-milling treatments to flatten the surface. Then, KPFM cross-section images were used for alignment to topography and to mark the locations of interfaces. C-AFM scans were all acquired using a single tip and the same scan conditions, at least two areas were examined to ensure the reliability of results. The FTO substrate was connected to the AFM stage and the applied bias voltage was 0.8 V.

X-ray Photoemission Spectroscopy (XPS) characterization: XPS measurements were performed on a Physical Electronics 5600 photoelectron spectrometer. Briefly, radiation was produced by a monochromatic 350 W Al Kα excitation centered at 1486.7 eV. XPS core-level spectra were collected using a step size of 0.1 eV and pass energy of 11.75 eV. The electron binding energy scale was calibrated using the Fermi edge of a copper substrate, cleaned with Argon ion bombardment. Peak areas were fit using a Gaussian-Lorentzian peak fitting algorithm with a Shirley background. Spectra taken with the Al source are typically assigned an uncertainty of 0.05 eV. Compositional analyses and deconvolutions are typically assigned an uncertainty of 5%.

Computation: The electronic properties were calculated using screened hybrid functional and van der Waals (vdW) interaction (HSE+vdW) to account the effects of organic molecules. We also employed the Grimme-D3 method to account for the van der Waals (vdW) effect. The spin-orbit coupling is not included in all calculations due to the small effects on the valence band. The calculations were performed with auxiliary density matrix method (ADMM) implemented in CP2K.

### Examples

Example 1. A composition comprising: a first layer comprising a first perovskite having a 3-dimensional (3D) crystalline structure; and a second layer comprising a second perovskite having a 2-dimensional (2D) crystalline structure, wherein: the 3D crystalline structure comprises ABX₃, the 2D crystalline structure comprises A′BX₄, A comprises a first cation, B comprises a second cation, X comprises an anion, and A′ comprises a third cation having a 2+ charge.

Example 2. The composition of Example 1, wherein A′ has a characteristic length between about 2.60 Å and about 10.10 Å.

Example 3. The composition of either Example 1 or Example 2, wherein A′ comprises an asymmetrical diammonium molecule.

Example 4. The composition of any one of Examples 1-3, wherein the 3D crystalline structure has a centrosymmetric orthorhombic space group Pbam.

Example 5. The composition of any one of Examples 1-4, wherein the 2D crystalline structure has a monoclinic P21/c space group.

Example 6. The composition of any one of Examples 1-5, wherein the diammonium molecule comprises at least one of N,N-dimethyl-1,3-propane diammonium (DMePDA²⁺) or 3-(aminomethyl)pyridinium (3-AMPY²⁺).

Example 7. The composition of any one of Examples 1-6, wherein the 2D crystalline structure comprises DMePDAPbI₄.

Example 8. The composition of any one of Examples 1-7, wherein DMePDAPbI₄ is characterized by a peak centered at about 575 nm, as measured by photoluminescence spectroscopy.

Example 9. The composition of any one of Examples 1-8, wherein DMePDAPbI₄ is characterized by a peak centered at about 620 nm, as measured by photoluminescence spectroscopy.

Example 10. The composition of any one of Examples 1-9, wherein A comprises at least one of methylammonium (MA), formamidinium (FA), or cesium.

Example 11. The composition of any one of Examples 1-10, wherein B comprises at least one of lead or tin.

Example 12. The composition of any one of Examples 1-11, wherein X comprises a halide.

Example 13. The composition of any one of Examples 1-12, wherein the halide comprises at least one of iodide, bromide, or chloride.

Example 14. The composition of any one of Examples 1-13, wherein: the first perovskite comprises FA_{1-x-y}MAₓCs_{y}Pb(I_{1-z}Br_{z})₃, 0≤x≤1, 0≤y≤1, and 0≤z≤1.

Example 15. The composition of any one of Examples 1-14, wherein the first perovskite is approximately equal to FA_{0.85}MA_{0.1}Cs_{0.05}PbI_{2.9}Br_{0.1}.

Example 16. The composition of any one of Examples 1-15, wherein y equals zero.

Example 17. The composition of any one of Examples 1-16, wherein the first perovskite is approximately equal to FA_{0.97}MA_{0.03}PbI_{2.91}Br_{0.09}.

Example 18. The composition of any one of Examples 1-17, wherein the second layer has a surface roughness less than or equal to about 14 nm.

Example 19. The composition of any one of Examples 1-18, wherein the surface roughness is between 5 nm and 14 nm, inclusively.

Example 20. The composition of any one of Examples 1-19, wherein the first layer has a thickness between 200 nm and 2000 nm.

Example 21. The composition of any one of Examples 1-20, wherein the second layer has a thickness between 1 nm and 150 nm.

Example 22. The composition of any one of Examples 1-21, wherein the composition has a yield mobility product (φΣμ) that is at least about between 35 cm2/Vs and 100 cm²/Vs cm2/Vs.

Example 23. The composition of any one of Examples 1-22, wherein the composition has a charge-carrier lifetime that is at least about between 1.3 microseconds and 6.0 microseconds.

Example 24. The composition of any one of Examples 1-23, wherein the composition has an out-of-plane charge transport that is about between (3-8)×10⁻³ cm²V⁻¹s⁻¹ and (7-21)×10⁻² cm²V⁻¹s⁻¹.

Example 25. The composition of any one of Examples 1-24, wherein the second layer uniformly covers the first layer.

Example 26. The composition of any one of Examples 1-25, wherein the composition is characterized by a peak between 8.5° and 8.7°, as measured by XRD.

Example 27. The composition of any one of Examples 1-26, wherein the composition is characterized by a free-carrier lifetime have a fast component value equal to at least 75 ns, as measured by photoluminescence (PL) decay.

Example 28. The composition of any one of Examples 1-27, wherein the composition is characterized by a free-carrier lifetime have a slow component value equal to at least 140 ns, as measured by photoluminescence (PL) decay.

Example 29. A device comprising: a first layer comprising a first perovskite having a 3-dimensional (3D) crystalline structure; and a second layer comprising a second perovskite having a 2-dimensional (2D) crystalline structure, wherein: the 3D crystalline structure comprises ABX₃, the 2D crystalline structure comprises A′BX₄, A comprises a first cation, B comprises a second cation, X comprises an anion, and A′ comprises a third cation having a 2+ charge.

Example 30. The device of Example 29, further comprising a hole-transfer layer (HTL), wherein the second layer is positioned between the first layer and the HTL.

Example 31. The device of either Example 29 or Example 30, wherein the HTL comprises at least one of spiro-OMeTAD, poly[bis(4-phenyl)(2,4,6-trimethylphenyl)amine, poly(N,N′-bis-4-butylphenyl-N,N′-bisphenyl)benzidine, and nickel oxide, and/or a suitable self-assembling monolayer such as at least one of [2-(3,6-dimethoxy-9H-carbazol-9-yl)ethyl]phosphonic acid, ([4-(3,6-dimethyl-9H-carbazol-9-yl)butyl]phosphonic acid), (4-(4-(3,6-dimethoxy-9H-carbazol-9yl)butyl)phosphonic acid, or ([2-(9H-carbazol-9-yl)ethyl]phosphonic acid.

Example 32. The device of any one of Examples 29-31, further comprising an electron-transfer layer (ETL), wherein the first layer is positioned between the second layer and the ETL.

Example 33. The device of any one of Examples 29-32, wherein the ETL comprises at least one of TiO₂, SnO₂, ZnO, In₂O₃, Nb₂O₅, Zn₂SnO₄, BaSnO₃ or SrTiO.

Example 34. A device comprising, in order: a glass substrate; a layer comprising fluorine-doped tin oxide; a layer comprising at least one of SnO₂ or TiO₂; a layer comprising a 3-dimensional (3D) perovskite; a layer comprising a 2-dimensional (2D) perovskite; a layer comprising a hole-transport material (HTL); and a metal layer.

Example 35. The device of Example 34, wherein the 2D perovskiter comprises DMcPDAPbI₄.

Example 36. The device of either Example 34 or Example 35, wherein the perovskite comprises FA_{1-x-y}MAₓCs_{y}Pb(I_{1-z}Br_{z})₃, 0≤x≤1, 0≤y≤1, and 0≤z≤1.

Example 37. The device of any one of Examples 34-36, wherein the HTL comprises at least one of spiro-OMeTAD, poly[bis(4-phenyl) (2,4,6-trimethylphenyl)amine, poly(N,N′-bis-4-butylphenyl-N,N′-bisphenyl)benzidine, and nickel oxide, and/or a suitable self-assembling monolayer such as at least one of [2-(3,6-dimethoxy-9H-carbazol-9-yl)ethyl]phosphonic acid, ([4-(3,6-dimethyl-9H-carbazol-9-yl)butyl]phosphonic acid), (4-(4-(3,6-dimethoxy-9H-carbazol-9yl)butyl)phosphonic acid, or ([2-(9H-carbazol-9-yl)ethyl]phosphonic acid.

Example 38. The device of any one of Examples 34-37, wherein the metal layer comprises at least one of silver, gold, copper, or molybdenum.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

1. A composition comprising:
a first layer comprising a first perovskite having a 3-dimensional (3D) crystalline structure; and
a plurality of second layers, each comprising a second perovskite having a 2-dimensional (2D) crystalline structure, wherein:
the 3D crystalline structure comprises ABX₃,
the 2D crystalline structure comprises A′BX₄,
A′ comprises at least one of N,N-dimethyl-1,3-propane diammonium (DMePDA²⁺) or 3-(aminomethyl)pyridinium (3-AMPY²⁺),
A comprises a first cation, B comprises a second cation, and X comprises an anion.

2. (canceled)

3. The composition of claim 1, wherein the 2D crystalline structure has a monoclinic P21/c space group.

4. The composition of claim 1, wherein A′ is DMePDA²⁺.

5. The composition of claim 1, wherein the 2D crystalline structure comprises DMePDAPbI₄.

6. The composition of claim 1, wherein:
the first perovskite comprises FA_{1-x-y}MAₓCs_{y}Pb(I_{1-z}Br_{z})₃,
0≤x≤1, 0≤y≤1, and 0≤z≤1.

7. The composition of claim 1, wherein the composition has a yield mobility product (φΣμ) that is between 35 cm²/Vs and 100 cm²/Vs cm²/Vs.

8. The composition of claim 1, wherein the composition has a charge-carrier lifetime that is between 1.3 microseconds and 6.0 microseconds.

9. The composition of claim 1, wherein the composition has an out-of-plane charge transport that is between (3-8)×10⁻³ cm²V⁻¹s⁻¹ and (7-21)×10⁻² cm²V⁻¹s⁻¹.

10. The composition of claim 1, wherein the plurality of second layers uniformly covers the first layer.

11. The composition of claim 1, wherein the composition is characterized by a peak between 8.5° and 8.7°, as measured by XRD.

12. The composition of claim 1, wherein the composition is characterized by a free-carrier lifetime having a fast component value equal to at least 75 ns, as measured by photoluminescence (PL) decay.

13. The composition of claim 1, wherein the composition is characterized by a free-carrier lifetime having a slow component value equal to at least 140 ns, as measured by photoluminescence (PL) decay.

14. A device comprising:
a first layer comprising a first perovskite having a 3-dimensional (3D) crystalline structure; and
a plurality of second layers, each comprising a second perovskite having a 2-dimensional (2D) crystalline structure, wherein:
the 3D crystalline structure comprises ABX₃,
the 2D crystalline structure comprises A′BX₄,
a distance between adjacent second layers is between 6.0 Å and 10.4 Å, A′ comprises at least one of N,N-dimethyl-1,3-propane diammonium (DMePDA²⁺) or 3-(aminomethyl)pyridinium (3-AMPY²⁺),
A comprises a first cation, B comprises a second cation, and X comprises an anion.

15. The device of claim 14, further comprising, in order:
a glass substrate;
a layer comprising fluorine-doped tin oxide;
a layer comprising at least one of SnO₂ or TiO₂;
the first layer;
the plurality of second layers;
a layer comprising a hole-transport material (HTL); and
a metal layer.

16. The device of claim 15, wherein the HTL comprises at least one of spiro-OMeTAD, poly[bis(4-phenyl)(2,4,6-trimethylphenyl)amine], poly(N,N′-bis-4-butylphenyl-N,N′-bisphenyl)benzidine, nickel oxide, [2-(3,6-dimethoxy-9H-carbazol-9-yl)ethyl]phosphonic acid, [4-(3,6-dimethyl-9H-carbazol-9-yl)butyl]phosphonic acid, [4-]4-(4-(3,6-dimethoxy-9H-carbazol-9yl)butyl)phosphonic acid, [2-(9H-carbazol-9-yl)ethyl]phosphonic acid, or a combination thereof.

17. The device of claim 15, wherein the metal layer comprises at least one of silver, gold, copper, molybdenum, or a combination thereof.

18. The device of claim 14, wherein A′ is DMePDA²⁺.
